(19) United States
(12) Patent Application Publication
(10) Pub. No.: US 2024/0170346 A1
(43) Pub. Date: May 23, 2024

(54) METHOD OF MANUFACTURING SEMICONDUCTOR DEVICE

(71) Applicant: RENESAS ELECTRONICS CORPORATION, Tokyo (JP)

(72) Inventor: Kosuke KITAICHI, Tokyo (JP)

(21) Appl. No.: 18/452,822

(22) Filed: Aug. 21, 2023

(30) Foreign Application Priority Data
Nov. 17, 2022 (JP) 2022-184178

(51) Int. Cl. H01L 21/66; H01L 21/78; H01L 29/40; H01L 29/66

(52) U.S. Cl. CPC H01L 22/14; H01L 21/78; H01L 29/402; H01L 29/66348

(57) ABSTRACT

In a wafer test step, a dummy semiconductor element formed in a scribe region of a semiconductor substrate is inspected by using a testing electrode provided in the scribe region and electrically connected to the dummy semiconductor element. In a dicing step, the scribe region of the semiconductor substrate is cut by using a dicing blade. The testing electrode includes a plurality of pad portions and a plurality of connection portions connecting the plurality of pad portions to each other. A width of each of the plurality of connection portions is larger than a width of the dicing blade, and smaller than a width of each of the plurality of pad portions. In plan view, the plurality of pad portions is arranged in a linear manner in a moving direction of the dicing blade, and the plurality of connection portions is arranged in a staggered manner in the moving direction.

### CROSS-REFERENCE TO RELATED APPLICATION

The disclosure of Japanese Patent Application No. 2022-184178 filed on Nov. 17, 2022, including the specification, drawings and abstract is incorporated herein by reference in its entirety.

### BACKGROUND

The present invention relates to a method of manufacturing a semiconductor device, and is suitably applicable to, for example, a method of manufacturing a semiconductor device including a step of cutting a semiconductor substrate.

There are disclosed techniques listed below.

[Patent Document 1] Japanese Unexamined Patent Application Publication No. 2005-340423

[Patent Document 2] Japanese Unexamined Patent Application Publication No. 2014-165388

[Patent Document 3] Japanese Unexamined Patent Application Publication No. 2015-56605

Japanese Unexamined Patent Application Publication No. 2005-340423 (Patent Document 1), Japanese Unexamined Patent Application Publication No. 2014-165388 (Patent Document 2) and Japanese Unexamined Patent Application Publication No. 2015-56605 (Patent Document 3) describe techniques related to a method of manufacturing a semiconductor device including a step of cutting a semiconductor substrate.

### SUMMARY

It is desired to improve reliability in a semiconductor device manufactured by a method of manufacturing a semiconductor device including a step of cutting a semiconductor substrate.

Other problems and novel characteristics will be apparent from the description of this specification and the accompanying drawings.

According to one embodiment, a method of manufacturing a semiconductor device includes the following steps (a) to (d). A step (a) is to prepare a semiconductor substrate including a plurality of chip formation regions and a scribe region positioned between the plurality of chip formation regions. A step (b) is to, after the step (a), form a semiconductor element in each of the plurality of chip formation regions and form a dummy semiconductor element in the scribe region. A step (c) is to, after the step (b), inspect the dummy semiconductor element by using a metal pattern provided at the scribe region. A step (d) is to, after the step (c), cut the scribe region of the semiconductor substrate by using a dicing blade. Here, the metal pattern includes a plurality of inspecting pad portions and a plurality of connection portions connecting the inspecting pad portions to each other. In plan view, a width of each of the plurality of connection portions is larger than a width of the dicing blade and smaller than a width of each of the plurality of inspecting pad portions. In plan view, the plurality of inspecting pad portions is arranged in a linear manner in the moving direction of the dicing blade, while the plurality of connection portions is arranged in a staggered manner in the moving direction of the dicing blade.

According to one embodiment, the reliability of the semiconductor device can be improved.

### BRIEF DESCRIPTIONS OF THE DRAWINGS

FIG. 1 is an upper surface view of a semiconductor device according to an embodiment.

FIG. 2 is a lower surface view of the semiconductor device according to the embodiment.

FIG. 3 is a plan perspective view of the semiconductor device according to the embodiment.

FIG. 4 is a cross-sectional view of a principal part of the semiconductor device according to the embodiment.

FIG. 5 is a cross-sectional view of a principal part of the semiconductor device according to the embodiment.

FIG. 6 is a cross-sectional view of a principal part of the semiconductor device according to the embodiment.

FIG. 7 is a plan view of a semiconductor substrate used in a process of manufacturing the semiconductor device of the embodiment.

FIG. 8 is a partially enlarged plan view in which a part of FIG. 7 is enlarged.

FIG. 9 is a cross-sectional view of a principal part in a step of manufacturing the semiconductor device according to the embodiment.

FIG. 10 is a cross-sectional view of the principal part in a step of manufacturing the semiconductor device, continued from FIG. 9.

FIG. 11 is a cross-sectional view of the principal part in another step of manufacturing the semiconductor device, continued from FIG. 10.

FIG. 12 is a cross-sectional view of the principal part in still another step of manufacturing the semiconductor device, continued from FIG. 11.

FIG. 13 is a cross-sectional view of the principal part in still another step of manufacturing the semiconductor device, continued from FIG. 12.

FIG. 14 is a cross-sectional view of the principal part in still another step of manufacturing the semiconductor device, continued from FIG. 13.

FIG. 15 is a cross-sectional view of the principal part in still another step of manufacturing the semiconductor device, continued from FIG. 14.

FIG. 16 is a step flowchart illustrating steps of manufacturing the semiconductor device of the embodiment.

FIG. 17 is a plan view illustrating a testing electrode formed in a scribe region of a semiconductor substrate.

FIG. 18 is a plan view illustrating the testing electrode formed in the scribe region of the semiconductor substrate.

FIG. 19 is a cross-sectional view of the scribe region of the semiconductor substrate in a stage before a dicing step.

FIG. 20 is a cross-sectional view of the scribe region of the semiconductor substrate in the stage before the dicing step.

FIG. 21 is a cross-sectional view of the scribe region of the semiconductor substrate in the stage before the dicing step.

FIG. 22 is a plan view illustrating a testing electrode of a study example formed in the scribe region of the semiconductor substrate.

FIG. 23 is a plan view illustrating the testing electrode of the study example formed in the scribe region of the semiconductor substrate.

FIG. 24 is a cross-sectional view of the scribe region of the semiconductor substrate in the stage before the dicing step.

FIG. 25 is a cross-sectional view of the scribe region of the semiconductor substrate in the stage before the dicing step.

FIG. 26 is a cross-sectional view illustrating a state of cutting of, by the dicing blade, the scribe region of the semiconductor substrate in which the testing electrode of the study example is formed.

FIG. 27 is a cross-sectional view illustrating a state of cutting of, by the dicing blade, the scribe region of the semiconductor substrate in which the testing electrode of the study example is formed.

FIG. 28 is a cross-sectional view illustrating a state after cutting of, by the dicing blade, the scribe region of the semiconductor substrate in which the testing electrode of the study example is formed.

FIG. 29 is a cross-sectional view illustrating a state after cutting of, by the dicing blade, the scribe region of the semiconductor substrate in which the testing electrode of the study example is formed.

FIG. 30 is a plan view illustrating a remaining cut-off piece of the testing electrode of the study example after the dicing step.

FIG. 31 is a cross-sectional view illustrating a state in which a scattered metal pattern adheres onto a protective film.

FIG. 32 is a cross-sectional view illustrating a state of cutting of, by the dicing blade, a scribe region of a semiconductor substrate in which a testing electrode of an embodiment is formed.

FIG. 33 is a cross-sectional view illustrating a state of cutting of, by the dicing blade, the scribe region of the semiconductor substrate in which the testing electrode of the embodiment is formed.

FIG. 34 is a cross-sectional view illustrating a state of cutting of, by the dicing blade, the scribe region of the semiconductor substrate in which the testing electrode of the embodiment is formed.

FIG. 35 is a cross-sectional view illustrating a state after cutting of, by the dicing blade, the scribe region of the semiconductor substrate in which the testing electrode of the embodiment is formed.

FIG. 36 is a cross-sectional view illustrating a state after cutting of, by the dicing blade, the scribe region of the semiconductor substrate in which the testing electrode of the embodiment is formed.

FIG. 37 is a cross-sectional view illustrating a state after cutting of, by the dicing blade, the scribe region of the semiconductor substrate in which the testing electrode of the embodiment is formed.

FIG. 38 is a plan view illustrating a remaining cut-off piece of the testing electrode after the dicing step.

FIG. 39 is a cross-sectional view illustrating a state in which a scattered metal pattern adheres onto a protective film.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference signs throughout all the drawings for explaining the embodiments, and the repetitive description thereof will be omitted. In addition, in the following embodiments, descriptions of the same or similar parts are not be repeated in principle unless particularly necessary.

In addition, in the drawings used in the embodiments, hatching may be omitted even in a cross-sectional view so as to make the drawings easy to see. In addition, hatching may be used even in plan view so as to make the drawings easy to see.

### Regarding Structure of Semiconductor Device

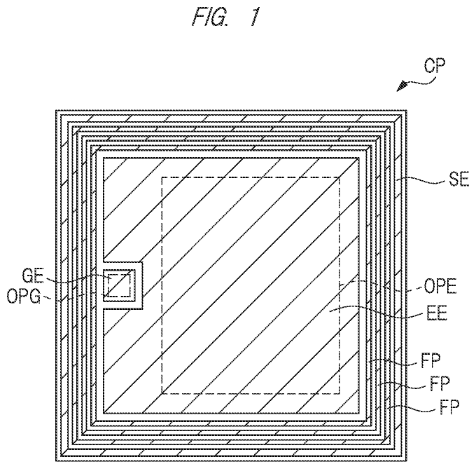

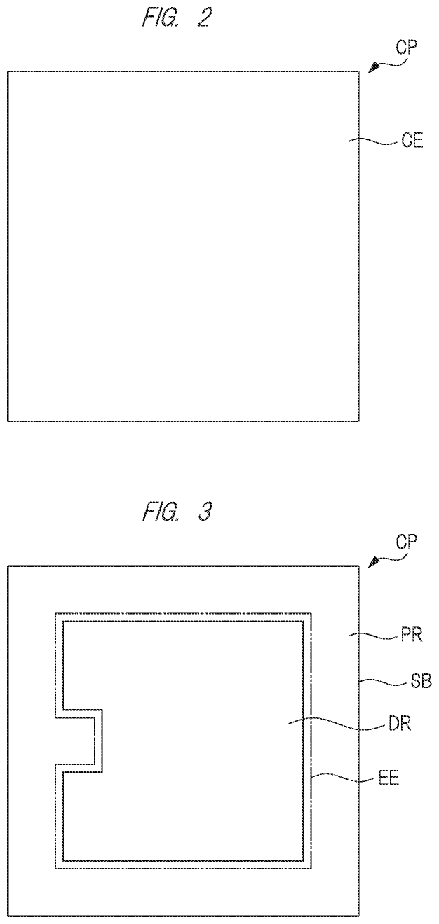

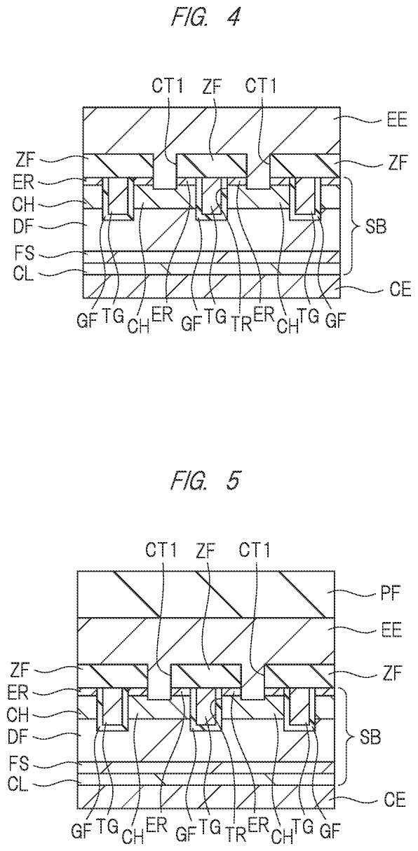

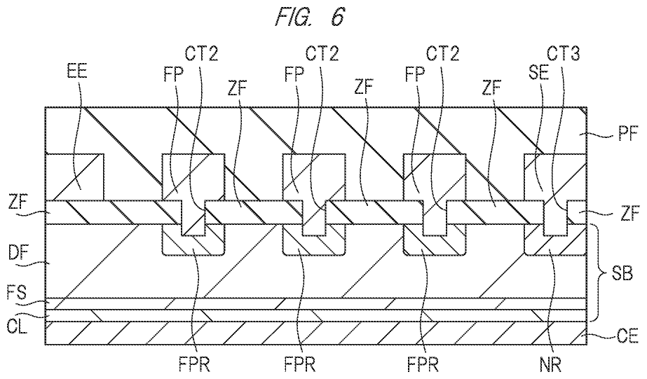

A structure of a semiconductor device (semiconductor chip) CP of this embodiment will be described with reference to FIGS. 1 to 6. FIG. 1 is an upper surface view of the semiconductor device CP of this embodiment, and FIG. 2 is a lower surface view (back surface view) of the semiconductor device CP of this embodiment. FIG. 3 is a plan perspective view of the semiconductor device CP of this embodiment, and each of FIGS. 4 to 6 is a cross-sectional view of a principal part of the semiconductor device CP of this embodiment. Each of FIGS. 4 and 5 is a cross-sectional view of principal parts of an element region DR illustrated in FIG. 3. However, FIG. 4 corresponds to a cross-sectional view in a region where an emitter electrode EE is exposed from an opening (opening for an emitter pad) of a protective film PF, and FIG. 5 corresponds to a cross-sectional view in a region where the emitter electrode EE is covered with the protective film PF. FIG. 6 is a cross-sectional view of a principal part of a peripheral region PR illustrated in FIG. 3.

The semiconductor device (semiconductor chip) CP of this embodiment is, for example, a power device including a power transistor (power system transistor), and the power transistor is formed on a semiconductor substrate SB configuring the semiconductor device CP. The semiconductor substrate SB configuring the semiconductor device CP is made of, for example, monocrystalline silicon, and has a main surface and a back surface opposite to the main surface. The semiconductor device CP and the semiconductor substrate SB configuring the semiconductor device CP have a rectangular planar shape.

The semiconductor device CP includes an emitter electrode EE, a gate electrode GE, a field plate electrode FP, and an outer peripheral electrode (outer wiring, outer peripheral collector electrode) SE, as uppermost layer wiring (uppermost conductor layer). The emitter electrode EE, the gate electrode GE, the field plate electrode FP, the outer peripheral electrode SE, and a testing electrode TE to be described below are all made of a metal material, and thus can be also regarded as metal electrode, metal wiring, or metal pattern.

The emitter electrode EE, the gate electrode GE, the field plate electrode FP, and the outer peripheral electrode SE are metal patterns of the same layer and are made of, for example, a laminated conductor film of a barrier conductor film and a main conductor film formed thereon. The barrier conductor film is made of, for example, titanium tungsten (TiW), and the main conductor film is thicker than the barrier conductor film and is made of, for example, an aluminum (Al) film or an aluminum alloy film.

In plan view, the emitter electrode EE and the gate electrode GE are disposed at a center of the semiconductor device CP, the field plate electrode FP is disposed on a peripherally outward side of (outside) the emitter electrode EE, and the outer peripheral electrode SE is disposed on a peripherally outward side of (outside) the field plate electrode FP. Planar dimensions (plane area) of the emitter electrode EE are larger than planar dimensions (area) of the gate electrode GE.

Further, in the present application, the plan view corresponds to a case of a view of a plan surface parallel to the main surface or the back surface of semiconductor substrate SB.

In addition, as seen from FIG. 3, an element region DR is disposed at a center of the main surface of semiconductor substrate SB configuring semiconductor device CP, and a peripheral region (outer peripheral region) PR is disposed on a peripherally outward side of the element region DR to surround the element region DR. The element region DR is a region where a semiconductor element is formed. A plurality of (a large number of) unit transistor cells are arranged in the element region DR, and the plurality of unit transistors are connected in parallel to configure a power transistor as a semiconductor element. The individual unit transistor cells have the same structure.

The emitter electrode EE is electrically connected to an emitter region of a power transistor formed in the semiconductor device CP (semiconductor substrate SB). The emitter electrode EE is formed to cover the entire element region DR, and thus the emitter electrode EE includes the element region DR in plan view.

The gate electrode GE is electrically connected to a gate (gate electrode) of the power transistor formed in the semiconductor device CP (semiconductor substrate SB). Although not illustrated in FIG. 1, a gate wiring unified with the gate electrode GE can also be provided.

In plan view, the field plate electrode FP is disposed on a peripherally outward side of (outside) the emitter electrode EE and the gate electrode GE to surround the emitter electrode EE and the gate electrode GE. The field plate electrode FP is an annular or frame-shaped electrode. In addition, in plan view, the outer peripheral electrode SE is disposed on the peripherally outward side of (outside) the field plate electrode FP to surround the field plate electrode FP. The outer peripheral electrode SE is an annular or frame-shaped electrode. Therefore, in plan view, the outer peripheral electrode SE is formed at an outer peripheral portion (outer edge portion) of the front surface of the semiconductor device CP to surround the emitter electrode EE and the gate electrode GE. The outer peripheral electrode SE is formed along the outer peripheral portion (outer edge portion) of the front surface of the semiconductor device CP. The field plate electrode FP is disposed between the emitter electrode EE/gate electrode GE and the outer peripheral electrode SE in plan view. The outer peripheral electrode SE is electrically connected to a collector region of the power transistor formed in the semiconductor device CP (semiconductor substrate SB). Therefore, the outer peripheral electrode SE can also be regarded as a collector electrode.

On the back surface of the semiconductor device CP, a collector electrode (back surface collector electrode) CE is formed as a back surface electrode. In the semiconductor device CP, the collector electrode CE is positioned on a side opposite to the emitter electrode EE, the gate electrode GE, the field plate electrode FP, and the outer peripheral electrode SE. The collector electrode CE is formed on the entire back surface of the semiconductor device CP. The collector electrode CE is electrically connected to a collector region of the power transistor formed in the semiconductor device CP (semiconductor substrate SB).

The emitter electrode EE and the gate electrode GE on the front surface side and the collector electrode CE on the back surface side function as external terminals (external connecting terminals) of the semiconductor device CP. Since the field plate electrode FP and the outer peripheral electrode SE are covered with the protective film PF and are not exposed, the field plate electrode FP and the outer peripheral electrode SE do not function as external terminals of the semiconductor device CP.

At least one field plate electrode FP is provided, but a plurality of field plate electrodes FP are preferably provided. In the case of FIGS. 1 and 6, an example with three field plate electrodes FP is illustrated. However, the number of field plate electrodes FP is not limited to three.

The unit transistor cells in the element region DR will be described below with reference to FIGS. 4 and 5. Each of FIGS. 4 and 5 is a cross-sectional view of a principal part illustrating an example of a unit transistor cell disposed in the element region DR in FIG. 3. However, as described above, FIG. 4 corresponds to a cross-sectional view in a region where the emitter electrode EE is exposed from an opening of the protective film PF, and FIG. 5 corresponds to a cross-sectional view in a region where the emitter electrode EE is covered with the protective film PF.

As illustrated in FIGS. 4 and 5, for example, a mesa insulated gate bipolar transistor (IGBT) is formed as the unit transistor cell. Hereinafter, the insulated gate bipolar transistor is simply referred to as a transistor. The transistor includes a p-type collector region CL, an n-type emitter region ER, an n⁻-type drift region DF and a p-type channel formation region CH therebetween, and a trench gate electrode TG.

That is, on the back surface side of the semiconductor substrate SB, the p-type collector region CL is formed from the back surface of the semiconductor substrate SB to a predetermined depth. The collector region CL is made of a p-type semiconductor region formed in the semiconductor substrate SB. The collector electrode CE is formed on the back surface of the semiconductor substrate SB, and the collector region CL is provided adjacent to the collector electrode CE and is electrically connected to the collector electrode CE. The collector electrode CE is made of, for example, a laminated film of an aluminum (Al) layer on the back surface of the semiconductor substrate SB, a titanium (Ti) layer thereon, a nickel (Ni) layer thereon, and a gold (Au) layer thereon. The collector electrode CE is formed on the entire back surface of the semiconductor substrate SB.

An n-type field stop region FS is formed between the p-type collector region CL and the n⁻-type drift region DF. The field stop region FS includes an n-type semiconductor region formed in the semiconductor substrate SB, and the drift region DF includes an n-type semiconductor region formed in the semiconductor substrate SB. In addition, an n-type impurity concentration of the field stop region FS is higher than an n-type impurity concentration of the drift region DF, and an n-type impurity concentration of the emitter region ER is higher than the n-type impurity concentration of the field stop region FS.

On the main surface side of the semiconductor substrate SB, the n-type emitter region ER is formed from the main surface of the semiconductor substrate SB to a predetermined depth. The emitter region ER includes an n-type semiconductor region formed in the semiconductor substrate SB. Of the drift region DF and the channel formation region CH, the channel formation region CH is adjacent to the emitter region ER, the emitter region ER is positioned above the channel formation region CH, and the channel formation region CH is interposed between the emitter region ER and the drift region DF. The p-type channel formation region CH is formed in the semiconductor substrate SB and includes a p-type semiconductor region.

In addition, in the element region DR, a trench (gate trench) TR extending from the main surface of the semiconductor substrate SB in the thickness direction of the semiconductor substrate SB is formed in the semiconductor substrate SB. The trench TR is formed to penetrate the emitter region ER and the channel formation region CH below the emitter region and reach the drift region DF. From another point of view, the channel formation region CH is formed between the adjacent trenches TR, and the emitter region ER is formed at a position above the channel formation region CH and adjacent to the trench TR.

The trench gate electrode TG is embedded in the trench TR via the gate insulating film GF. The gate insulating film GF is made of, for example, a silicon oxide film and is formed on a bottom surface and side surfaces of the trench TR. The trench gate electrode TG is made of, for example, a polycrystalline silicon film doped with an n-type impurity (for example, phosphorus). The trench gate electrode TG functions as a gate (gate electrode) of the unit transistor cell. The trench gate electrode TG is electrically connected to the gate electrode GE.

In addition, an insulating film (interlayer insulating film) ZF is formed on the main surface of the semiconductor substrate SB to cover the upper surface of the trench gate electrode TG and the emitter region ER. The insulating film ZF is made of, for example, a silicon oxide film. The insulating film ZF is formed on the entire main surface of the semiconductor substrate SB and functions as an interlayer insulating film. The emitter electrode EE, the gate electrode GE, the field plate electrode FP, and the outer peripheral electrode SE are formed on the insulating film ZF. However, in the element region DR, the emitter electrode EE is formed on the insulating film ZF.

In addition, in the element region DR, a contact hole (connection trench) CT1 that penetrates the insulating film ZF and the emitter region ER and reaches the channel formation region CH is formed. The emitter electrode EE is embedded in the contact hole CT1. The emitter electrode EE is in contact with the emitter region ER exposed from a side surface of the contact hole CT1 and is electrically connected to the emitter region ER. In addition, the emitter electrode EE is in contact with the p-type channel formation region CH exposed from a bottom portion of the contact hole CT1 and is electrically connected to the p-type channel formation region CH. Further, when a p-type semiconductor region having a higher impurity concentration than that of the p-type channel formation region CH may be provided at a position adjacent to the bottom portion of the contact hole CT1, the emitter electrode EE may be electrically connected to the p-type channel formation region CH through the p-type semiconductor region. In plan view, the emitter electrode EE is formed over the entire element region DR in which the plurality of unit transistor cells configuring the power transistor are formed.

The semiconductor device CP includes an insulating protective film (surface protective film, passivation film) PF as an uppermost film (insulating film). The protective film PF is made of an insulating film, but is preferably made of a resin film such as a polyimide resin. The emitter electrode EE, the gate electrode GE, the field plate electrode FP, and the outer peripheral electrode SE are covered with the protective film PF. That is, the protective film PF is formed on the insulating film ZF to cover the emitter electrode EE, the gate electrode GE, the field plate electrode FP, and the outer peripheral electrode SE.

However, an opening for a pad (bonding pad) is formed in the protective film PF. An opening OPE for an emitter pad of the protective film PF is formed to be included in the emitter electrode EE in plan view, and a part of the emitter electrode EE is exposed from the opening OPE for the emitter pad of the protective film PF. The emitter pad (bonding pad for emitter) is formed by the emitter electrode EE exposed from the opening OPE for the emitter pad of the protective film PF. In addition, an opening OPG for a gate pad of the protective film PF is formed to be included in the gate electrode GE in plan view, and a part of the gate electrode GE is exposed from the opening OPG for the gate pad of the protective film PF. A gate pad (bonding pad for gate) is formed by the gate electrode GE exposed from the opening OPG for the gate pad of the protective film PF. The field plate electrode FP and the outer peripheral electrode SE are entirely covered with the protective film PF and are not exposed from the protective film PF.

The trench gate electrodes TG of the plurality of unit transistor cells formed in the element region DR are electrically connected to each other and electrically connected to the gate electrode GE through a gate connection portion (not illustrated) unified with the trench gate electrodes TG, a gate wiring (not illustrated) unified with the gate electrode GE, and the like.

In addition, the emitter regions ER of the plurality of unit transistor cells configuring the power transistor are electrically connected to the emitter electrode EE and are electrically connected to each other through the emitter electrode EE.

In addition, the collector regions of the plurality of unit transistor cells configuring the power transistor are electrically connected to each other through the collector region CL and the collector electrode CE.

Here, the case of use of the IGBT as the semiconductor element formed in the element region DR has been described. As another form, a power metal oxide semiconductor field effect transistor (MOSFET) may be formed as the semiconductor element formed in the element region DR, instead of the IGBT described above. In this case, the emitter region ER becomes a source region, the emitter electrode EE becomes a source electrode, the collector region CL is not formed, the collector electrode CE becomes a drain electrode, and the testing electrode TE to be described below becomes a source electrode. Further, in the MOSFET, the gate insulating film is not limited to the oxide film (silicon oxide film). In addition, as the semiconductor element formed in the element region DR, another transistor such as a reverse-conducting (RC)-IGBT or a bipolar transistor may be applied as the unit transistor cell, instead of the IGBT or the power MOSFET. In addition, a diode can also be applied as a semiconductor element formed in the element region DR. In this case, one of the emitter electrode EE and the collector electrode CE becomes an anode electrode, the other becomes a cathode electrode, and the gate electrode GE is not formed.

Next, a peripheral region (PR) of the semiconductor device CP (semiconductor substrate SB) will be described with reference to FIGS. 1 and 6.

As illustrated in FIG. 6, in the peripheral region of the semiconductor device CP, a p-type semiconductor region FPR and an n-type semiconductor region NR are formed on the main surface side of the semiconductor substrate SB. The p-type semiconductor region FPR is formed to surround the element region DR in plan view. In plan view, the p-type semiconductor region FPR has an annular or frame-shaped pattern and functions as a field limiting ring. The p-type semiconductor region FPR extends along the field plate electrode FP to be positioned below the field plate electrode FP, and the number of p-type semiconductor regions FPR is equal to the number of field plate electrodes FP. The n-type semiconductor region NR has an annular or frame-shaped pattern and extends along the outer peripheral electrode SE to be positioned below the outer peripheral electrode SE.

A contact hole (connection trench) CT2 penetrating the insulating film ZF is formed on the p-type semiconductor region FPR, and the contact hole CT2 is filled with the field plate electrode FP. The field plate electrode FP is in contact with the p-type semiconductor region FPR and is electrically connected to the p-type semiconductor region FPR. A contact hole (connection trench) CT3 penetrating the insulating film ZF is formed on the n-type semiconductor region NR, and the contact hole CT3 is filled with the outer peripheral electrode SE. The outer peripheral electrode SE is in contact with the n-type semiconductor region NR and is electrically connected to the n-type semiconductor region NR. The outer peripheral electrode SE is electrically connected to the collector electrode CE through the semiconductor substrate SB.

During an operation of the semiconductor device CP, a voltage (for example, several hundreds of V such as about 750 V) considerably higher than a voltage (for example, about 0 V to 30 V) applied to the emitter electrode EE and the gate electrode GE is applied to the collector electrode CE. The voltage applied to the collector electrode CE is also applied to the outer peripheral electrode SE through the semiconductor substrate SB configuring the semiconductor device CP. Therefore, a large potential difference is generated between the emitter electrode EE and the outer peripheral electrode SE and between the gate electrode GE and the outer peripheral electrode SE. However, an electric field distribution inside the semiconductor substrate SB in the peripheral region PR is made uniform by the p-type semiconductor region FPR (field limiting ring) provided in the semiconductor substrate SB and the field plate electrode FP provided on the semiconductor substrate SB. In addition, the potential of the upper surface of the semiconductor substrate SB is fixed by using the field plate electrode FP. Therefore, a withstand voltage of the peripheral region PR of the semiconductor device CP can be improved, and the reliability of the semiconductor device CP can be improved.

### Method of Manufacturing Semiconductor Device

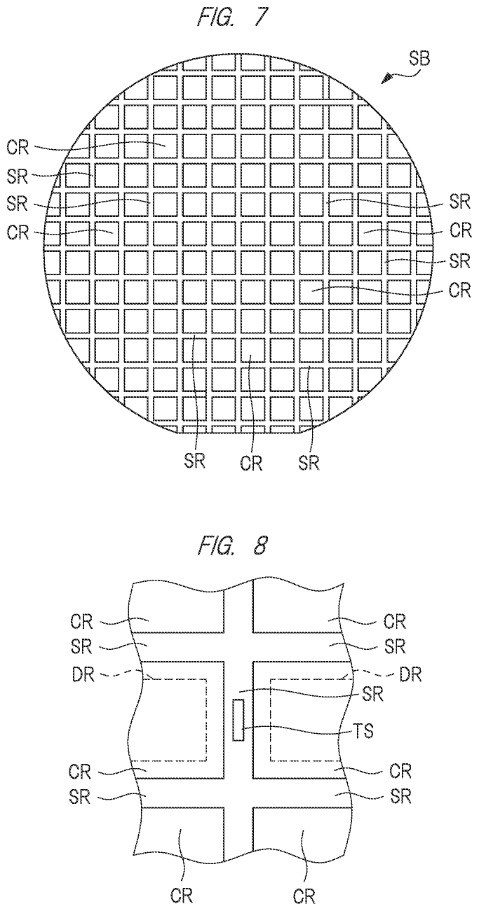

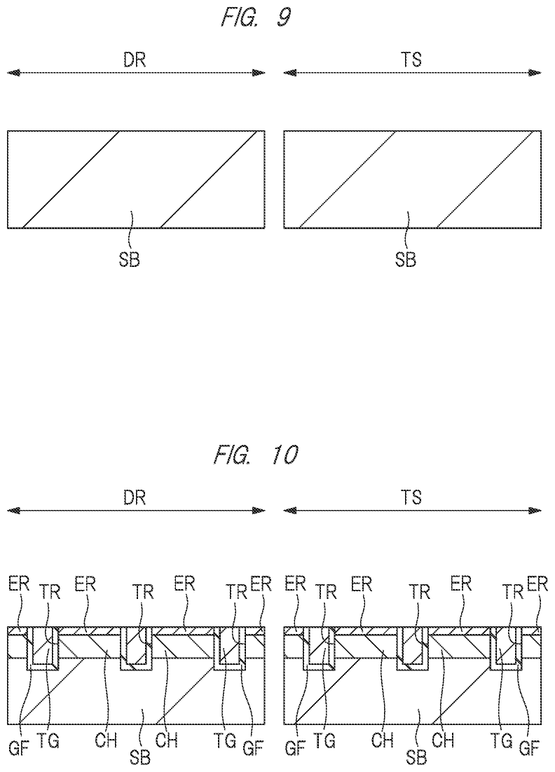

Steps of manufacturing the semiconductor device of this embodiment will be described with reference to the drawings. FIG. 7 is a plan view of a semiconductor substrate (semiconductor wafer) SB used in the steps of manufacturing the semiconductor device of this embodiment, and FIG. 8 is a partially enlarged plan view illustrating a part of FIG. 7 in an enlarged manner. Each of FIGS. 9 to 15 is a cross-sectional view of a principal part in the steps of manufacturing the semiconductor device of this embodiment. In each of FIGS. 9 to 15, a cross section illustrated on the left side in the drawing is a cross section corresponding to FIG. 5 (that is, a cross section of the element region DR included in a chip formation region CR), and a cross section illustrated on the right side in the drawing is a cross section of a test element region TS included in a scribe region SR.

First, as illustrated in FIGS. 7 to 9, a semiconductor substrate (semiconductor wafer) SB is provided (prepared). At this stage, the semiconductor substrate SB is a semiconductor wafer having a substantially circular shape in plan view. The semiconductor substrate SB has a main surface and a back surface opposite thereto. The semiconductor substrate SB is made of, for example, monocrystalline silicon, and an n⁻-type semiconductor substrate doped with an n-type impurity can be used. As the semiconductor substrate SB, an epitaxial wafer in which an epitaxial semiconductor layer is formed on a semiconductor substrate can also be used.

Here, as illustrated in FIGS. 7 and 8, the semiconductor substrate SB has the chip formation region (semiconductor chip region, semiconductor device region) CR which is a region from which the semiconductor chip (semiconductor device) is to be acquired, and a scribe region (cutting region) SR between the chip formation regions CR, and each chip formation region CR is surrounded by the scribe region SR in plan view. That is, in the semiconductor substrate SB, the plurality of chip formation regions CR are arranged in an array, and a region between the chip formation regions CR arranged in the array corresponds to the scribe region SR. Thus, in the semiconductor substrate SB, the plurality of chip formation regions CR arranged in the array is partitioned by the scribe region SR. In a dicing step (cutting step), the semiconductor substrate SB is cut (diced) along the scribe region SR, so that chip formation regions CR are divided into individual pieces to form respective semiconductor chips (semiconductor devices CP), and the semiconductor chip corresponds to the semiconductor device CP. The chip formation region CR and the scribe region SR correspond to different planar regions on the main surface of the same semiconductor substrate SB.

The scribe region SR of the semiconductor substrate SB includes the test element region TS where a semiconductor element for a test (examination or inspection) is formed. The test element region TS can also be regarded as a region where a test element group (TEG) is formed. In addition, the chip formation region CR of the semiconductor substrate SB includes the above-described element region DR. When the chip formation region CR is individually divided to manufacture the semiconductor device CP, the element region DR included in the chip formation region CR is also included in the semiconductor device CP. At this stage, the semiconductor element is formed in neither the element region DR nor the test element region TS. In subsequent steps, a semiconductor element (here, IGBT) that can be used in the manufactured semiconductor device CP (semiconductor device CP as a product) is formed in the element region DR of the chip formation region CR. In the test element region TS of the scribe region SR, a semiconductor element (here, IGBT) having the same structure as the semiconductor element formed in the element region DR of the chip formation region CR is formed in the same steps as those of the semiconductor element formed in the element region DR of the chip formation region CR. However, planar dimensions (plane area) of the test element region TS are smaller than planar dimensions (plane area) of the element region DR. In a wafer step to be described below, the test element region TS is included in the scribe region SR, and when the chip formation region CR is individually divided to manufacture the semiconductor device CP, a part or entirety of the test element region TS is not included in the semiconductor device CP. The semiconductor element (here, IGBT) formed in the test element region TS is a testing semiconductor element (so-called dummy semiconductor element) and is not a semiconductor element used in the semiconductor device CP as a product. In this embodiment, the semiconductor element formed in the element region DR and the dummy semiconductor element formed in the test element region TS are vertical semiconductor elements such as IGBTs. Here, the vertical semiconductor element corresponds to a semiconductor element through which a current flows in a thickness direction of the semiconductor substrate.

Next, as illustrated in FIG. 10, after the trenches TR are formed in the semiconductor substrate SB in the element region DR and the test element region TS by etching, the gate insulating film GF is formed on an inner surface (side surface and bottom surface) of the trench TR by a thermal oxidation method or the like. Then, on the main surface of the semiconductor substrate SB, a conductor film (for example, a polycrystalline silicon film) for forming the trench gate electrode TG is formed to fill the trench TR by a chemical vapor deposition (CVD) method or the like, and then the conductor film is etched back. Consequently, the trench gate electrode TG is formed by the conductor film remaining in the trench TR via the gate insulating film GF.

Next, p-type channel formation regions CH are formed in the semiconductor substrate SB in the element region DR and the test element region TS by using an ion implantation method, and then an n-type emitter region ER is formed by using an ion implantation method. Then, the p-type semiconductor region FPR (see FIG. 6) is formed in the semiconductor substrate SB in the peripheral region PR of the chip formation region CR by using an ion implantation method, and the n-type semiconductor region NR (see FIG. 6) is formed by using an ion implantation method. An order of formation of the p-type channel formation region CH, the n-type emitter region ER, the p-type semiconductor region FPR, and the n-type semiconductor region NR is optional. In addition, any one of the p-type channel formation region CH, the n-type emitter region ER, the p-type semiconductor region FPR, and the n-type semiconductor region NR can be formed before the trench TR is formed.

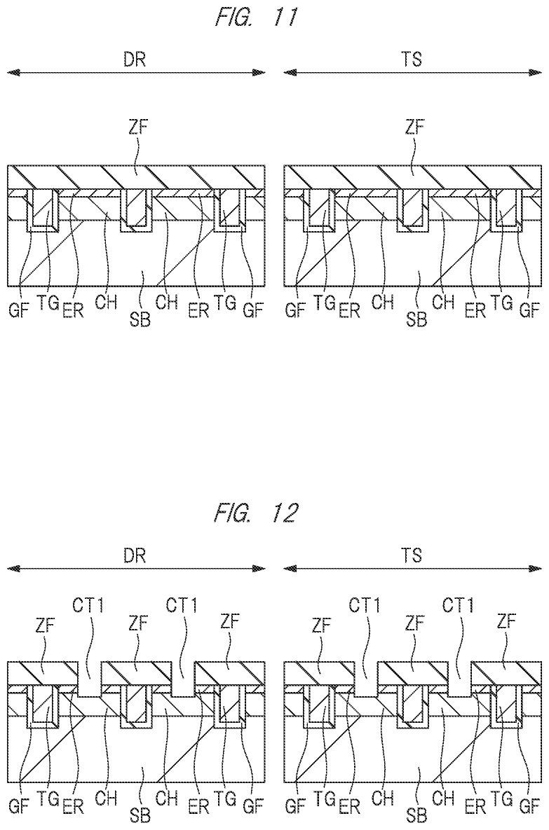

Next, as illustrated in FIG. 11, an insulating film ZF is formed on the main surface of the semiconductor substrate SB to cover the trench gate electrodes TG. The insulating film ZF is made of, for example, a single film of a silicon oxide film, a laminated film of a thin silicon nitride film and a silicon oxide film thicker than the thin silicon nitride film, or the like. The insulating film ZF can function as an interlayer insulating film.

Next, as illustrated in FIG. 12, contact holes CT1, CT2, and CT3 (see FIG. 6 for contact holes CT2, CT3) are formed in the insulating film ZF by using a photolithography technique and an etching technique. In the element region DR and the test element region TS, the contact hole CT1 is formed to penetrate the insulating film ZF and the emitter region ER and reach the channel formation region CH.

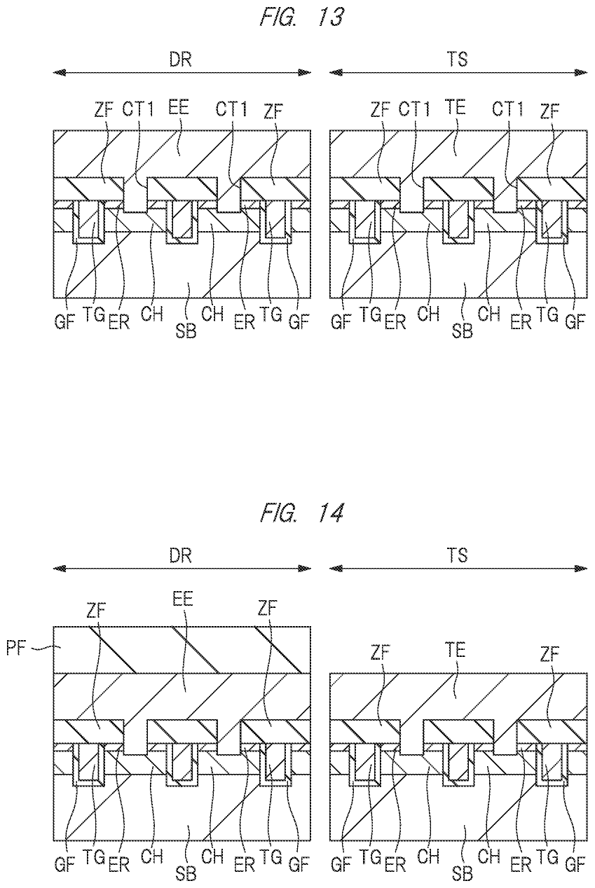

Next, as illustrated in FIG. 13, a metal film is formed on the insulating film ZF to fill the contact holes CT1, CT2, and CT3, and then the metal film is patterned by using a photolithography technique and an etching technique to form the emitter electrode EE, the testing electrode TE, the gate electrode GE, the field plate electrode FP, and the outer peripheral electrode SE. Further, although not illustrated in FIG. 13, the gate electrode GE, the field plate electrode FP, and the outer peripheral electrode SE are illustrated in FIGS. 1 and 6.

The testing electrode (metal pattern) TE is electrically connected to the semiconductor element (dummy semiconductor element) formed in the test element region TS. Specifically, the testing electrode TE is electrically connected to the emitter region of the semiconductor element (IGBT) formed in the test element region TS and can function as an emitter electrode for the semiconductor element (IGBT) formed in the test element region TS. The testing electrode TE is formed to cover the entire test element region TS, and thus the testing electrode TE includes the test element region TS in plan view.

The test element region TS will be described more specifically. As illustrated in FIG. 13, in the test element region TS, the contact hole (connection trench) CT1 that penetrates the insulating film ZF and the emitter region ER and reaches the channel formation region CH is formed, and the contact hole CT1 is filled with the testing electrode TE. The testing electrode TE is in contact with the emitter region ER exposed from the side surface of the contact hole CT1 and is electrically connected to the emitter region ER. In addition, the testing electrode TE is in contact with the p-type channel formation region CH exposed form the bottom portion of the contact hole CT1 and is electrically connected to the p-type channel formation region CH. Further, a p-type semiconductor region having a higher impurity concentration than that of the p-type channel formation region CH may be provided at a position adjacent to the bottom portion of the contact hole CT1, and the testing electrode TE may be electrically connected to the p-type channel formation region CH through the p-type semiconductor region. In plan view, the testing electrode TE is formed over the entire test element region TS in which the plurality of unit transistor cells configuring the power transistor are formed.

The trench gate electrode TG formed in the test element region TS is electrically connected to the gate electrode GE. As another form, a gate electrode (not illustrated) electrically connected to the trench gate electrode TG formed in the test element region TS can be also formed on the insulating film ZF of the scribe region SR.

Next, as illustrated in FIGS. 14 and 6, a protective film PF made of polyimide resin or the like is formed on the insulating film ZF to cover the emitter electrode EE, the testing electrode TE, the gate electrode GE, the field plate electrode FP, and the outer peripheral electrode SE. Then, the openings OPE and OPG (see FIG. 1) are formed in the protective film PF by using a photolithography technique and an etching technique. When the openings OPE and OPG are formed, the protective film PF of the scribe region SR is also removed. FIG. 14 illustrates this stage. Consequently, in the scribe region SR, the protective film PF is not formed on the insulating film ZF, and the testing electrode TE is exposed without being covered with the protective film PF. A part of the emitter electrode EE is exposed from the emitter pad opening OPE of the protective film PF to form an emitter pad, and the gate electrode GE is exposed from the gate pad opening OPG of the protective film PF to form a gate pad.

Next, the back surface side of the semiconductor substrate SB is ground as necessary to make the semiconductor substrate SB thin.

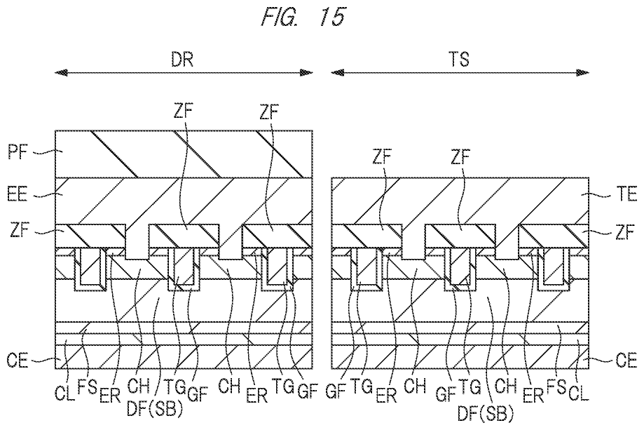

Next, as illustrated in FIG. 15, the n-type field stop region FS is formed on the back surface side of the semiconductor substrate SB by using an ion implantation method, and then the p-type collector region CL is formed by using an ion implantation method.

Next, the collector electrode CE is formed on the back surface of the semiconductor substrate SB by using a sputtering method or the like.

In this manner, a wafer process is performed.

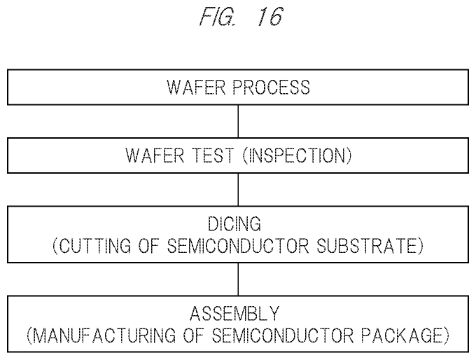

FIG. 16 is a step flowchart illustrating steps of manufacturing the semiconductor device. As illustrated in FIG. 16, the steps of manufacturing the semiconductor device sequentially include a wafer process, a wafer test step (wafer inspection step), a dicing step (cutting step of semiconductor substrate SB), and an assembly step. The description with reference to FIGS. 7 to 15 corresponds to the wafer process.

Details of the wafer process are described above. The wafer process includes a step of preparing the semiconductor substrate SB including a plurality of chip formation regions CR and a scribe region SR positioned between two chip formation regions CR of the plurality of chip formation regions CR, the two chip formation regions being adjacent to each other. The wafer process further includes, after the step of preparing the semiconductor substrate SB, a step of forming a semiconductor element in each of (the element regions DR of) the plurality of chip formation regions CR and forming a dummy semiconductor element in (the test element region TS of) the scribe region SR.

After the wafer process, a wafer test (wafer inspection) step is performed. The wafer test step is an inspection step performed before the dicing step (cutting step of the semiconductor substrate SB). In the wafer test step, the semiconductor element (dummy semiconductor element) formed in the test element region TS of the scribe region SR is inspected (electrically tested) by using the testing electrode provided in the scribe region SR of the semiconductor substrate SB (semiconductor wafer). As described above, the testing electrode TE is electrically connected to the semiconductor element (dummy semiconductor element) formed in the test element region TS of the scribe region SR. Therefore, the semiconductor element (dummy semiconductor element) formed in the test element region TS can be inspected by using the testing electrode TE. In this manner, the semiconductor element formed in the element region DR can be indirectly inspected (evaluated).

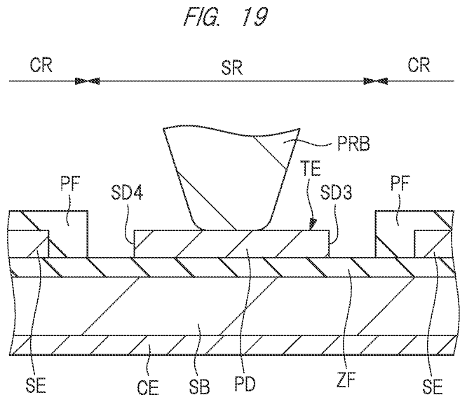

In the wafer test step, a testing (inspecting) probe PRB (see FIG. 19 to be described below) is brought into contact with (pressed against) the testing electrode TE. The semiconductor element formed in the test element region TS is inspected (electrically tested), and the semiconductor element formed in the element region DR can be evaluated by using its result. Since the semiconductor element formed in the test element region TS and the semiconductor element formed in the element region DR have substantially the same structure and are formed through the same steps, the semiconductor element formed in the element region DR can be indirectly evaluated by inspecting the semiconductor element formed in the test element region TS.

After the wafer test step, the dicing step is performed. The dicing step is a step of cutting the scribe region SR of the semiconductor substrate SB by using a dicing blade (cutting blade) DBR. The dicing blade DBR is illustrated in FIGS. 26, 27, and 32 to 34 to be described below. In the dicing step, the semiconductor substrate SB is cut along the scribe region SR by using the rotating dicing blade DRB. In other words, in the dicing step, the scribe region SR of the semiconductor substrate SB is cut (removed) by using the rotating dicing blade. Consequently, the chip formation regions CR in the semiconductor substrate SB are individually divided, and a semiconductor chip (semiconductor device CP) including the individually divided chip formation region CR is acquired.

After the dicing step, an assembly step is performed. The assembly step corresponds to a step of manufacturing a semiconductor package by using the semiconductor chip (semiconductor device CP) acquired in the dicing step. For example, the semiconductor device CP is mounted on a die pad of a lead frame (not illustrated) to electrically connect the die pad and the collector electrode CE of the semiconductor device CP, and then the plurality of leads of the lead frame and the emitter pad (emitter electrode EE) and the gate pad (gate electrode GE) of the semiconductor device CP are electrically connected to each other via a conductive connection member (for example, a bonding wire). Then, the semiconductor device CP, the conductive connection member, the die pad, and the leads are resin-sealed, and then the leads and the die pad are cut and separated from the lead frame. In this manner, the semiconductor package can be manufactured.

### Regarding Testing Electrode TE

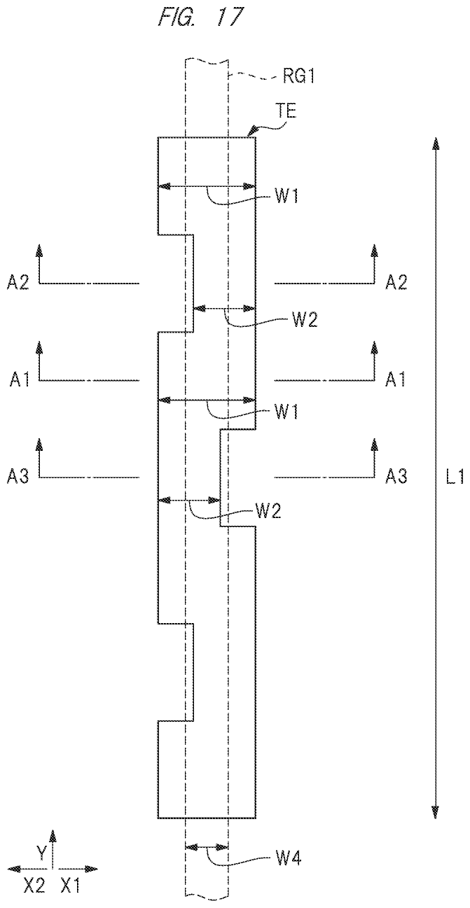

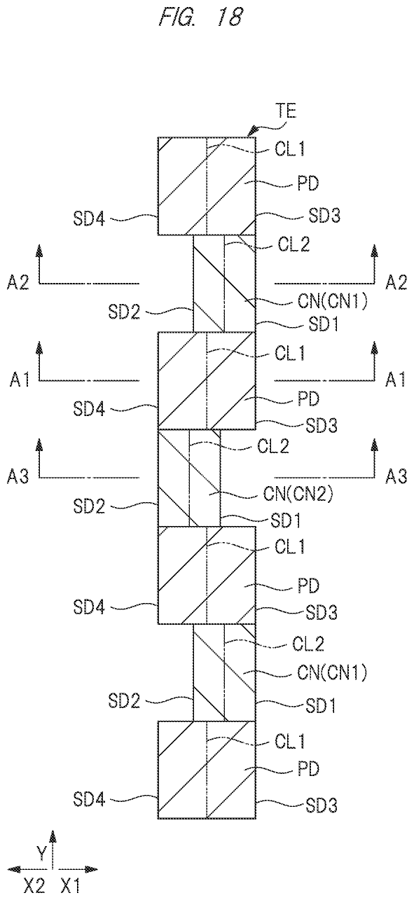

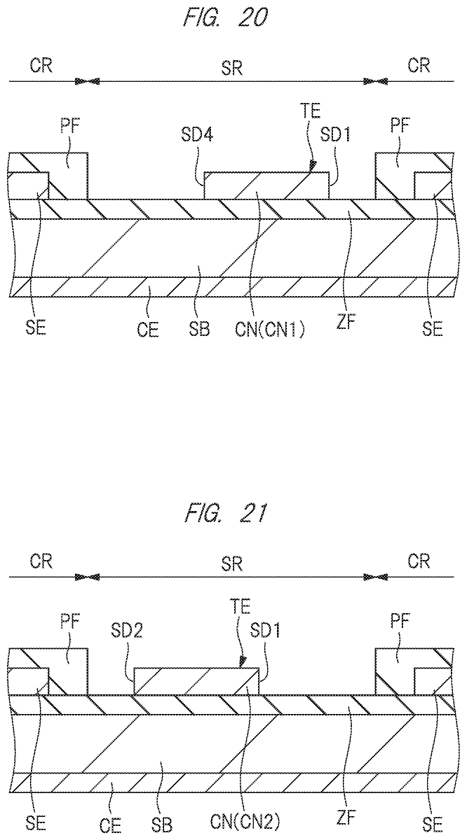

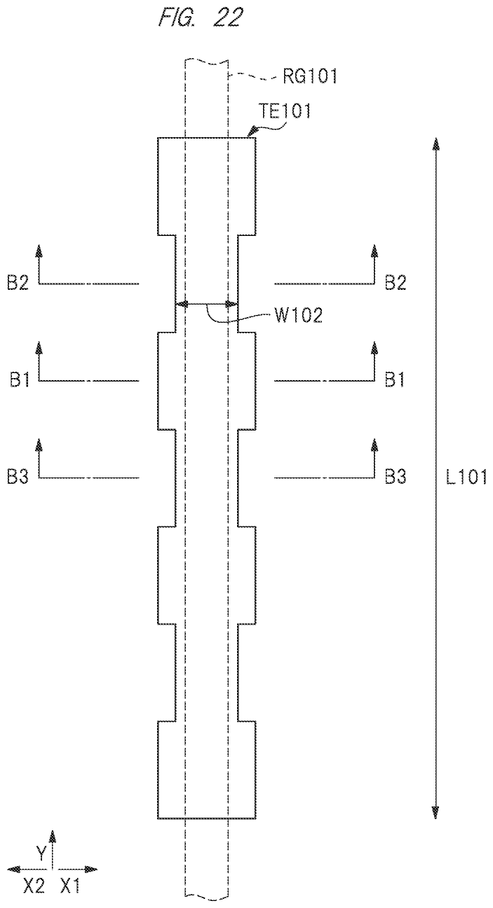

FIG. 17 is a plan view illustrating the testing electrode TE formed in the scribe region SR of the semiconductor substrate SB. In FIG. 17, a cutting region RG1 which is a region cut (removed) by the dicing blade DRB in the dicing step is indicated by a dotted line. That is, in the dicing step, the rotating dicing blade DRB moves along the cutting region RG1 illustrated in FIG. 17, and the cutting region RG1 is cut (removed) by the movement. In addition, FIG. 18 is also a plan view illustrating the testing electrode TE formed in the scribe region SR of the semiconductor substrate SB. In FIG. 18, a pad portion PD and a connection portion CN configuring the testing electrode TE are hatched in different directions to facilitate discrimination between the pad portion PD and the connection portion CN. In addition, each of FIGS. 19 to 21 is a cross-sectional view of the scribe region SR of the semiconductor substrate SB in a stage before the dicing step is performed. A cross-sectional view taken along line A1-A1 in FIGS. 17 and 18 corresponds to FIG. 19, a cross-sectional view taken along line A2-A2 in FIGS. 17 and 18 corresponds to FIG. 20, and a cross-sectional view taken along line A3-A3 in FIGS. 17 and 18 corresponds to FIG. 21. Further, in FIGS. 19 to 21, illustration of the semiconductor element (IGBT) formed in the test element region TS of the scribe region SR is omitted for simplification of the drawing. However, practically, the semiconductor element (IGBT) is formed below the testing electrode TE as illustrated in FIG. 15. In addition, FIG. 19 illustrates a state in which the testing (inspecting) probe PRB is brought into contact with the pad portion PD of the testing electrode TE in the wafer test step. In addition, a Y direction illustrated in FIGS. 17 and 18 is a scanning direction (moving direction, or cutting direction) of the dicing blade in the dicing step. An X1 direction and an X2 direction illustrated in FIGS. 17 and 18 are directions intersecting the Y direction, and more specifically, are directions orthogonal to the Y direction. The X1 direction and the X2 direction are opposite directions (reverse directions) to each other. Further, the X1 direction, the X2 direction, and the Y direction are also parallel to the main surface or the back surface of the semiconductor substrate SB.

As illustrated in FIGS. 17 and 18, the testing electrode TE is configured to include a plurality of pad portions (inspecting pad portions) PD and a plurality of connection portions CN connecting the pad portions PD. The plurality of pad portions PD and the plurality of connection portions CN configuring the testing electrode TE are unified. In the wafer test step, the testing (inspecting) probe PRB is brought into contact with the plurality of pad portions PD of the testing electrode TE (see FIG. 19). Therefore, the pad portion PD can function as an inspecting pad portion.

The plurality of pad portions PD configuring the testing electrode TE are arranged to be separated from each other in the Y direction. The connection portion CN unified with the pad portions PD is interposed between the pad portions PD adjacent to each other in the Y direction. Therefore, the pad portions PD adjacent to each other in the Y direction are connected to each other by the connection portion CN. Since the plurality of pad portions PD configuring the testing electrode TE are arranged to be separated from each other in the Y direction, the connection portion CN connecting the pad portions PD adjacent to each other in the Y direction extends in the Y direction.

The plurality of pad portions PD configuring the testing electrode TE preferably have the same planar shape and planar dimensions (plane area). The pad portion PD has a quadrangular (preferably rectangular) planar shape, and more specifically, more preferably has a rectangular shape having a side parallel to the Y direction and a side parallel to the X1 direction. Further, since the X1 direction and the X2 direction are opposite to each other, the side parallel to the X1 direction is also a side parallel to the X2 direction.

Each of the plurality of connection portions CN configuring the testing electrode TE has a quadrangular (preferably rectangular) planar shape, and more specifically, preferably has a rectangular shape having a side parallel to the Y direction and a side parallel to the X1 direction. In addition, in the case of FIGS. 17 and 18, the plurality of pad portions PD configuring the testing electrode TE are arranged at equal intervals in the Y direction, but in this case, the lengths (dimensions) of the plurality of connection portions CN configuring the testing electrode TE are the same in the Y direction between the plurality of connection portions CN.

A width W1 of the pad portion PD is larger than a width W2 of the connection portion CN (that is, W1>W2). Here, the width W1 of the pad portion PD corresponds to a dimension (length) of the pad portion PD in the X1 direction. In addition, the width W2 of the connection portion CN corresponds to a dimension (length) of the connection portion CN in the X1 direction. In order to easily bring the probe PRB into contact with the pad portion PD in the wafer test step, the width W1 of the pad portion PD is set to be large. As an example, the width W1 of the pad portion PD can be set to about 50 μm to 80 μm. On the other hand, in the wafer test step, it is not necessary to bring the probe PRB into contact with the connection portion CN. Therefore, the width W2 of the connection portion CN does not need to be large in order to easily bring the probe PRB into contact. However, in order to accurately form the testing electrode TE, there is a limit to a reduction in the width W2 of the connection portion CN, and it is preferable to secure the width W2 of the connection portion CN to some extent. As an example, the width W1 of the pad portion PD can be set to about 30 μm to 50 μm.

In this embodiment, the width W2 of the connection portion CN is smaller than the width W1 of the pad portion PD, and a width (thickness) W3 of the dicing blade DBR used in the dicing step is smaller than the width W2 of the connection portion CN (that is, W1>W2>W3). Further, the width (thickness) W3 of the dicing blade DBR is illustrated in FIGS. 26, 27, and 32 to 34 to be described below. The width (thickness) W3 of the dicing blade DBR substantially coincides with width (dimension in the X1 direction) W4 of the cutting region RG1 illustrated in FIG. 17. This embodiment is a technique effectively applied to a case where the width W2 of the connection portion CN is desired to be larger than the width W3 of the dicing blade DBR used in the dicing step, in other words, a case where the width W3 of the dicing blade DBR is desired to be smaller than the width W2 of the connection portion CN.

In plan view, the plurality of pad portions PD configuring the testing electrode TE is arranged in a linear manner in the Y direction. Further, the term “linear” described herein means that each of the plurality of pad portions PD configuring the testing electrode TE is arranged in the linear manner in the Y direction as illustrated in FIG. 18 without being shifted toward the X1 direction or the X2 direction in plan view. In addition, this means that center lines CLI of the plurality of pad portions PD configuring the testing electrode TE overlap (coincide) with each other in the Y direction. In other words, in plan view, the center lines CLI of all of the plurality of pad portions PD configuring the testing electrode TE are positioned on the same straight line along the Y direction.

Here, in plan view, the connection portions CN have respective sides SD1 and respective sides SD2 which extend in the Y direction and are positioned on opposite sides in the X1 direction, and the pad portions PD have respective sides SD3 and respective sides SD4 which extend in the Y direction and are positioned on opposite sides in the X1 direction. In the plurality of pad portions PD and the plurality of connection portions CN configuring the testing electrode TE, the respective sides SD3 of the plurality of pad portions PD and the respective sides SD1 of the plurality of connection portions CN are sides on the same side (right side in the case of FIG. 18), and the respective sides SD4 of the plurality of pad portions PD and the respective sides SD2 of the plurality of connection portions CN are sides on the same side (left side in the case of FIG. 18). Therefore, in the plurality of pad portions PD and the plurality of connection portions CN configuring the testing electrode TE, the side SD3 of each pad portion PD and the side SD1 of each connection portion CN face the protective film PF of the chip formation region CR adjacent to the testing electrode TE in the X1 direction. In addition, in the plurality of pad portions PD and the plurality of connection portions CN configuring the testing electrode TE, the side SD4 of each pad portion PD and the side SD2 of each connection portion CN face the protective film PF of the chip formation region CR adjacent to the testing electrode TE in the X2 direction. That is, the protective film PF is present in the X1 direction of the side SD3 of each pad portion PD and the side SD1 of each connection portion CN, and the protective film PF is present in the X2 direction of the side SD4 of each pad portion PD and the side SD2 of each connection portion CN.

In plan view, the center line CL1 of the pad portion PD is a line at which a distance from the side SD3 of the pad portion PD1 to the center line CL1 and a distance from the side SD4 to the center line CL1 are the same as each other.

The plurality of connection portions CN configuring the testing electrode TE is arranged in a staggered manner in the Y direction. Further, the term “staggered” described herein means that the plurality of connection portions CN configuring the testing electrode TE include a connection portion CN1 shifted toward the X1 direction and a connection portion CN2 shifted toward the X2 direction, in which the connection portion CN1 shifted toward the X1 direction and the connection portion CN2 shifted toward the X2 direction are alternately arranged via the pad portion PD as illustrated in FIG. 18.

Here, among the plurality of connection portions CN configuring the testing electrode TE, the connection portion CN shifted toward the X1 direction is referred to as the connection portion CN1, and the connection portion CN shifted toward the X2 direction is referred to as a connection portion CN2. A center line CL2 of the connection portion CN1 is shifted toward the X1 direction from the center line CL1 of the pad portion PD. In addition, the center line CL2 of the connection portion CN2 is shifted toward the X2 direction from the center line CL1 of the pad portion PD. That is, the center line CL2 of the connection portion CN1 and the center line CL2 of the connection portion CN2 do not overlap (do not coincide) with each other in the Y direction.

In plan view, the center line CL2 of the connection portion CN is a line at which a distance from the side SDI to the center line CL2 of the connection portion CN and a distance from the side SD2 to the center line CL2 are the same as each other.

As seen from FIGS. 17 and 18, the side SD1 of the connection portion CN1 is not included in the cutting region RG1 which is a region cut by the dicing blade BRD in the dicing step, but the side SD2 of the connection portion CN1 is included in the cutting region RG1. In addition, the side SD1 of the connection portion CN2 is included in the cutting region RG1 which is the region cut by the dicing blade BRD in the dicing step, but the side SD2 of the connection portion CN2 is not included in the cutting region RG1. In order to achieve this, the connection portion CN1 and the connection portion CN2 is arranged to be shifted (in a staggered manner).

In addition, in the case of FIGS. 17 and 18, in plan view, the side SD1 of the connection portion CN1 is aligned with the side SD3 of the pad portion PD positioned adjacent to the connection portion CN1 (positioned on the same straight line in the Y direction). In addition, the side SD2 of the connection portion CN2 is aligned with the side SD4 of the pad portion PD positioned adjacent to the connection portion CN2 (positioned on the same straight line in the Y direction).

### Background to Study

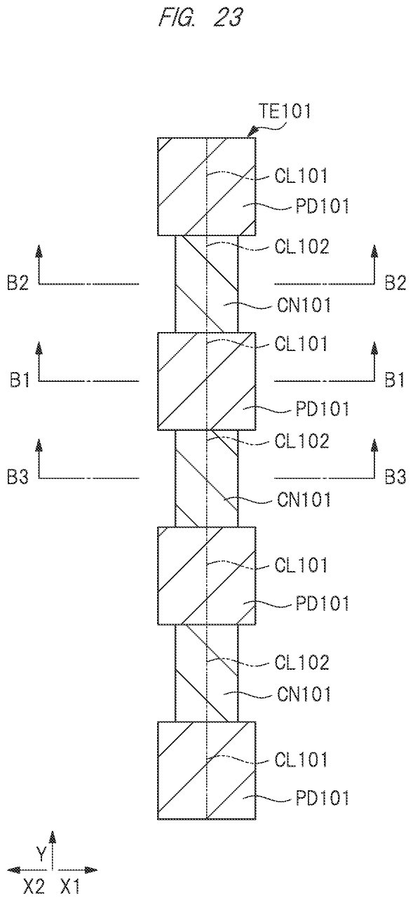

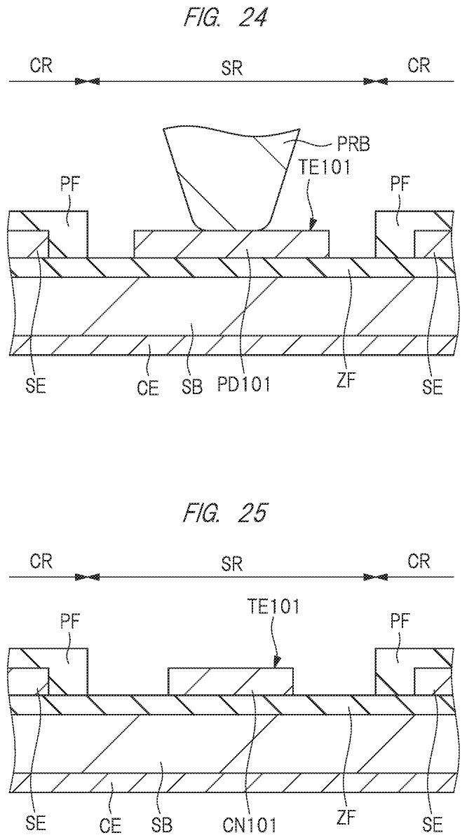

FIGS. 22 and 23 are plan views each illustrating a testing electrode TE101 of a study example formed in the scribe region SR of the semiconductor substrate SB. FIG. 22 corresponds to FIG. 17, and FIG. 23 corresponds to FIG. 18. In FIG. 22, a cutting region RG101 which is a region cut (removed) by the dicing blade in the dicing step is indicated by a dotted line. In addition, FIGS. 24 and 25 are cross-sectional views each illustrating the scribe region SR of the semiconductor substrate SB in a stage before the dicing step is performed. A cross-sectional view at a position of the line B1-B1 in FIGS. 22 and 23 correspond to FIG. 24, and a cross-sectional view at a position of the line B2-B2 in FIGS. 22 and 23 correspond to FIG. 25. A cross-sectional view taken along line B3-B3 in FIGS. 22 and 23 is almost the same as that in FIG. 25. Further, in FIGS. 24 and 25, illustration of the semiconductor element (IGBT) formed in the test element region of the scribe region SR is omitted for simplification of the drawing. In addition, FIG. 24 illustrates a state in which the testing (inspecting) probe PRB is brought into contact with a pad portion PD101 of the testing electrode TE101 in the wafer test step.

As illustrated in FIGS. 22 and 23, the testing electrode TE101 of the study example is configured to include a plurality of pad portions PD101 and a plurality of connection portions CN101 connecting the pad portions PD101, and the plurality of pad portions PD101 and the plurality of connection portions CN101 are unified. In the wafer test step, the testing (inspecting) probe PRB is brought into contact with the plurality of pad portions PD101 of the testing electrode TE101 (see FIG. 24).

The plurality of pad portions PD101 configuring the testing electrode TE101 are arranged to be separated from each other in the Y direction, and the connection portion CN101 unified with the pad portions PD101 is interposed between the pad portions PD101 adjacent in the Y direction. Since the plurality of pad portions PD101 configuring the testing electrode TE101 are arranged to be separated from each other in the Y direction, the connection portion CN101 connecting the pad portions PD101 adjacent to each other in the Y direction extends in the Y direction.

In a case of the study example illustrated in FIGS. 22 and 23, the plurality of pad portions PD101 and the plurality of connection portions CN101 configuring the testing electrode TE101 is arranged in the linear manner in the Y direction in plan view. That is, in plan view, the plurality of pad portions PD101 and the plurality of connection portions CN101 configuring the testing electrode TE101 is arranged in the linear manner in the Y direction without being shifted toward the X1 direction or the X2 direction. Specifically, in the testing electrode TE101 of the study example, a center line CL101 of each of the plurality of pad portions PD101 and a center line CL102 of each of the plurality of connection portions CN101 overlap (coincide) in the Y direction. In other words, in the testing electrode TE101 of the study example, the center lines CL101 of the plurality of pad portions PD101 and the center lines CL102 of the plurality of connection portions CN101 are positioned on the same straight line along the Y direction in plan view.

Meanwhile, in recent years, along with high functionality of the semiconductor device or the like, the number of evaluation items in the wafer test step tends to increase. Therefore, in recent years, an area of the test element region (region where the dummy semiconductor element for inspection is formed) provided in the scribe region of the semiconductor substrate has been increased. The test element region corresponds to the test element region TS.

Therefore, in the scribe region of the semiconductor substrate, a length of the test element region in the Y direction tends to increase. This is because it is necessary to increase the length of the test element region in the Y direction in order to increase the area of the test element region provided in the scribe region without increasing a width of the scribe region in the semiconductor substrate. Further, an increase in the width of the scribe region in the semiconductor substrate is undesirable because the increase reduces the number of semiconductor chips that can be acquired from the semiconductor substrate.

When a semiconductor element formed in the test element region is a vertical semiconductor element such as an IGBT, it is necessary to provide a testing electrode (corresponding to the testing electrode TE or the testing electrode TE101) to cover the entire test element region. The larger the length of the test element region in the Y direction is, the larger the length of the testing electrode in the Y direction inevitably is.

When the length of the testing electrode in the Y direction is large, it is desirable to provide a plurality of pad portions in the testing electrode and bring the testing probe into contact with the plurality of pad portions in the wafer test step. Therefore, it is desirable that the testing electrode on the test element region in the scribe region includes a plurality of pad portions and a plurality of connection portions connecting the pad portions. Therefore, in the case of this embodiment illustrated in FIGS. 17 and 18, the testing electrode TE on the test element region TS of the scribe region SR of the semiconductor substrate SB is configured to include the plurality of pad portions PD and the plurality of connection portions CN connecting the pad portions PD. In addition, in the case of the study example illustrated in FIGS. 22 and 23, the testing electrode TE101 on the test element region in the scribe region of the semiconductor substrate is configured to include the plurality of pad portions PD101 and the plurality of connection portions CN101 connecting the pad portions PD101. As described above, the lengths of the testing electrodes TE and TE101 in the Y direction tend to increase, and are, for example, 300 μm or more.

The width (dimension in the X1 direction) of the pad portion (PD or PD101) of the testing electrode (TE or TE101) needs to be increased to some extent so as not to cause a problem in bringing the testing probe into contact with the pad portion. On the other hand, the width (dimension in the X1 direction) of the connection portion (CN or CN101) of the testing electrode (TE or TE101) can be made smaller than the width of the pad portion (PD or PD101), but there is still a limit to making the width smaller. Since it is difficult to form a thin metal pattern, it is necessary to secure the width of the connection portion (CN or CN101) of the testing electrode (TE or TE101) to some extent in order to accurately form the testing electrode (TE or TE101).

On the other hand, in recent years, the width (thickness) of the dicing blade used in the dicing step has become thin. This is because there is a demand for a reduction in the width of the scribe region in order to increase the number of semiconductor chips that can be acquired from the semiconductor wafer, and accordingly, there is a demand for a reduction in the thickness of the dicing blade.

As a result, the thickness of the dicing blade may have to be smaller than the width of the connection portion (CN or CN101) of the testing electrode (TE or TE101). That is, the width (thickness) W3 of the dicing blade DBR may become smaller than the width W2 of the connection portion CN of the testing electrode TE (that is, W2>W3), or the width (thickness) W3 of the dicing blade DBR may become smaller than a width W102 of the connection portion CN101 of the testing electrode TE101 (that is, W102>W3). In this case, remaining cut-off pieces of the testing electrode (TE or TE101) are produced after the dicing step, and there is a risk of scattering of the pieces to be re-adhered onto the chip formation region CR (or the acquired semiconductor chip) to cause a defect. This will be described with reference to FIGS. 26 to 30.

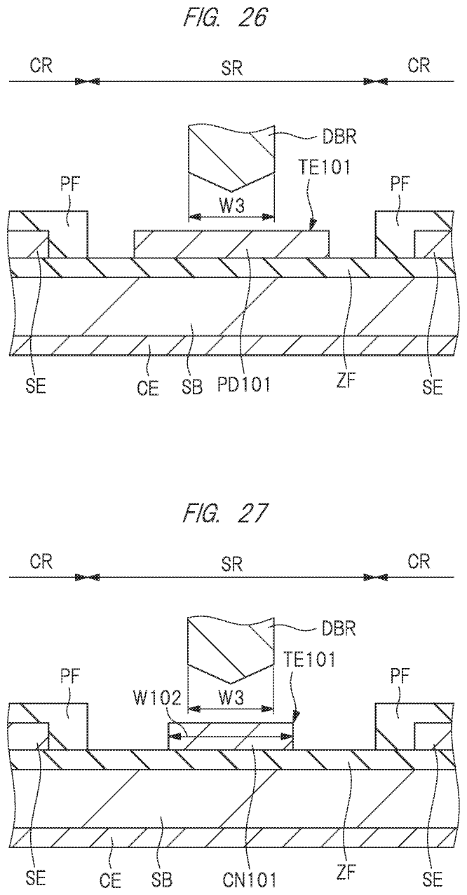

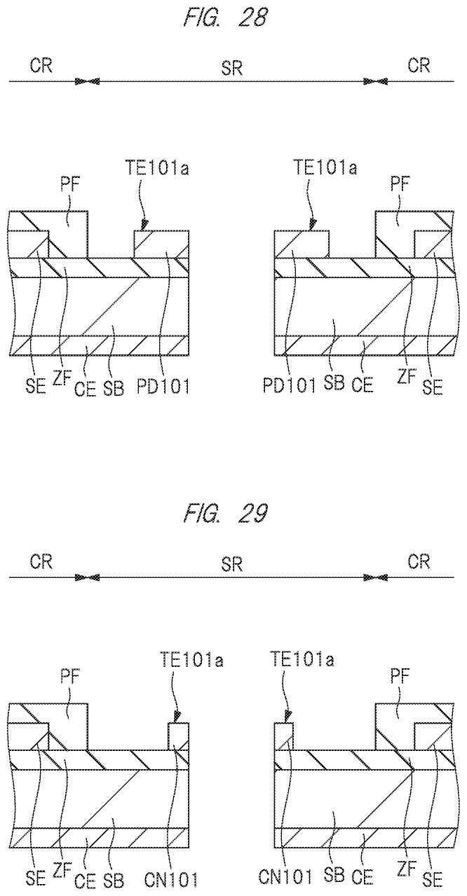

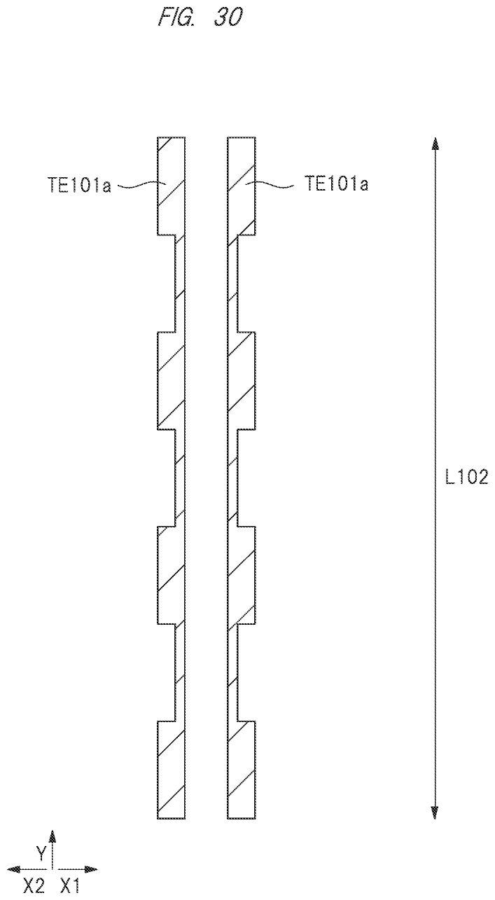

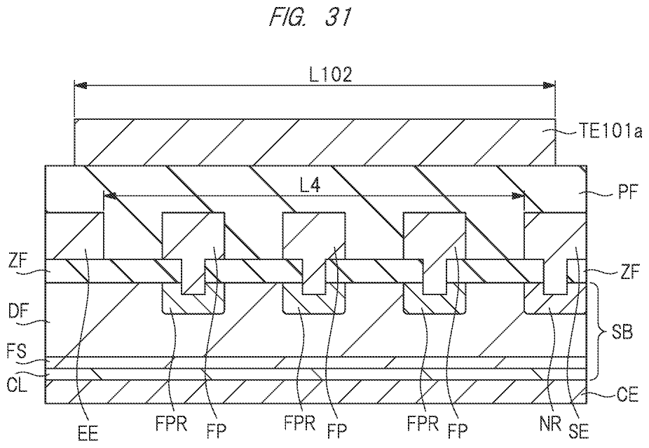

FIGS. 26 and 27 are cross-sectional views each illustrating a state of cutting of, by the dicing blade DBR, the scribe region SR of the semiconductor substrate SB in which the testing electrode TE101 of the study example is formed, and FIGS. 28 and 29 are cross-sectional views each illustrating a state of cutting (state after cutting), by the dicing blade DBR, the scribe region SR of the semiconductor substrate SB in which the testing electrode TE101 of the study example is formed. Each of FIGS. 26 and 28 corresponds to the cross section taken along line B1-B1 in FIGS. 22 and 23 (thus, the cross section corresponding to FIG. 24), and each of FIGS. 27 and 29 corresponds to the cross section taken along line B2-B2 in FIGS. 22 and 23 (thus, the cross section corresponding to FIG. 25). FIG. 30 is a plan view illustrating the remaining cut-off pieces of the testing electrode TE101 of the study example after the dicing step.

In the dicing step, as illustrated in FIGS. 26 to 29, the scribe region SR of the semiconductor substrate SB in which the testing electrode TE101 of the study example is formed is cut by the dicing blade DBR. In this case, when the fact that the width W3 of the dicing blade DBR is smaller than the width W102 of the connection portion CN101 of the testing electrode TE101 (W102>W3) is reflected, elongated metal patterns (metal pieces) TE101a formed by the remaining cut-off pieces of the testing electrode TE101 remain as illustrated in FIG. 30. The metal patterns TE101a illustrated in FIG. 30 correspond to the remaining pieces of the testing electrode TE101 illustrated in FIG. 22, from which a portion overlapping the cutting region RG 101 cut by the dicing blade DBR is removed. A length (length in the Y direction) L102 of the elongated metal pattern TE101a is the same as the length (length in the Y direction) L101 of the testing electrode TE101 before the dicing step (that is, L101=L102).

When the elongated metal patterns TE101a formed by the remaining cut-off pieces of the testing electrode TE101 are produced after the dicing step, there is the risk of scattering of the elongated metal patterns TE101a to re-adhering on the chip formation region CR (or the acquired semiconductor chip) to cause the defect. However, the longer the length of the metal pattern TE101a is, the higher the risk of the defect is.

FIG. 31 is a cross-sectional view illustrating a state in which the scattered metal pattern TE101a adheres onto the protective film PF, and a cross section corresponding to FIG. 6 is illustrated. FIG. 31 illustrates a state in which the scattered metal pattern TE101a adheres onto the protective film PF to straddle the emitter electrode EE and the outer peripheral electrode SE.

A voltage applied to the collector electrode CE can be applied to the outer peripheral electrode SE through the semiconductor substrate SB. Therefore, a considerably large potential difference (for example, several hundreds of V such as about 750 V) is generated between the emitter electrode EE and the outer peripheral electrode SE and between the gate electrode GE and the outer peripheral electrode SE. When the metal pattern TE101a is adhered to straddle the emitter electrode EE and the outer peripheral electrode SE as illustrated in FIG. 31, the electric field distribution inside the semiconductor substrate SB in the peripheral region PR is unordered due to the adhered metal pattern TE101a, and there is a risk of reduction in a withstand voltage of the peripheral region PR of the semiconductor device CP, which results in reduction in the reliability of the semiconductor device CP. Similarly, when the metal pattern TE101a is re-adhered to straddle the gate electrode GE and the outer peripheral electrode SE, the electric field distribution inside the semiconductor substrate SB in the peripheral region PR is unordered due to the adhered metal pattern TE101a, there is the risk of reduction in the withstand voltage of the peripheral region PR of the semiconductor device CP, which results in reduction in the reliability of the semiconductor device CP.

Therefore, it is desirable to prevent the scattered metal pattern TE101a from adhering onto the protective film PF to straddle the emitter electrode EE and the outer peripheral electrode SE. In addition, it is desirable to prevent the scattered metal pattern TE101a from adhering onto the protective film PF to straddle the gate electrode GE and the outer peripheral electrode SE. For this purpose, it is effective to shorten the length L102 of the elongated metal pattern TE101a remaining after the dicing step. However, the larger the length L101 of the testing electrode TE101 in the Y direction is, the larger the length L102 of the elongated metal pattern TE101a remaining after the dicing step also undesirably is. Therefore, when the testing electrode TE101 of the study example is used, it is difficult to shorten the length L102 of the metal pattern TE101a remaining after the dicing step.

### Regarding Main Features and Effects

The testing electrode (metal pattern) TE provided in the scribe region SR of the semiconductor substrate SB includes a plurality of pad portions (inspecting pad portions) PD and a plurality of connection portions CN respectively provided between the plurality of pad portions PD, each of the plurality of connection portions connecting two pad portions PD of the plurality of pad portions PD, the two pad portions being adjacent to each other.

One of the main features of this embodiment is that the width W2 of the connection portion CN in the X1 direction is larger than the width (thickness) W3 of the dicing blade DBR and smaller than the width W1 of each of the plurality of pad portions PD in plan view (that is, W1>W2>W3). In plan view, the plurality of pad portions PD configuring the testing electrode TE is arranged in the linear manner in the Y direction (the moving direction of the dicing blade DRB), while the plurality of connection portions CN configuring the testing electrode TE is arranged in the staggered manner in the Y direction.

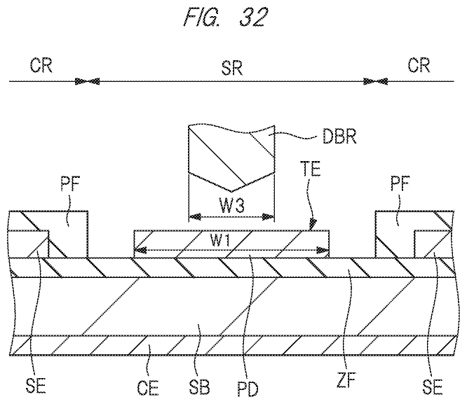

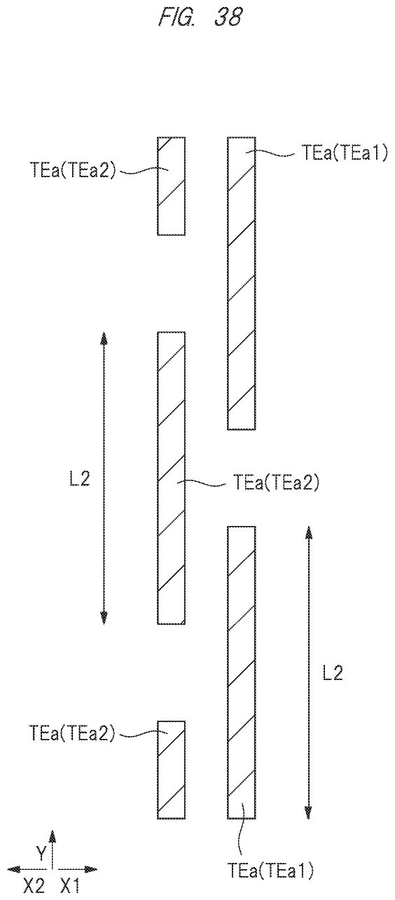

Consequently, the connection portion CN1 shifted toward the X1 direction and the connection portion CN2 shifted toward the X2 direction are alternately arranged to interpose the pad portion PD therebetween. As a result, an elongated metal pattern TEa (see FIG. 38 to be described below) formed by the remaining cut-off piece of the testing electrode TE is produced after the dicing step, but a length (length in the Y direction) L2 of the metal pattern TEa can be made shorter than a length (length in the Y direction) L1 of the testing electrode TE before the dicing step (that is, L2<L1). Therefore, even when the elongated metal pattern TEa formed by the remaining cut-off piece of the testing electrode TE is produced after the dicing step so that the elongated metal pattern TEa scatters and is re-adhered onto the chip formation region CR (or the acquired semiconductor chip), the risk of causing the defect can be reduced. Consequently, the reliability of the manufactured semiconductor device can be improved. In addition, a manufacturing yield of the semiconductor device can be improved. This point will be specifically described with reference to FIGS. 32 to 39.

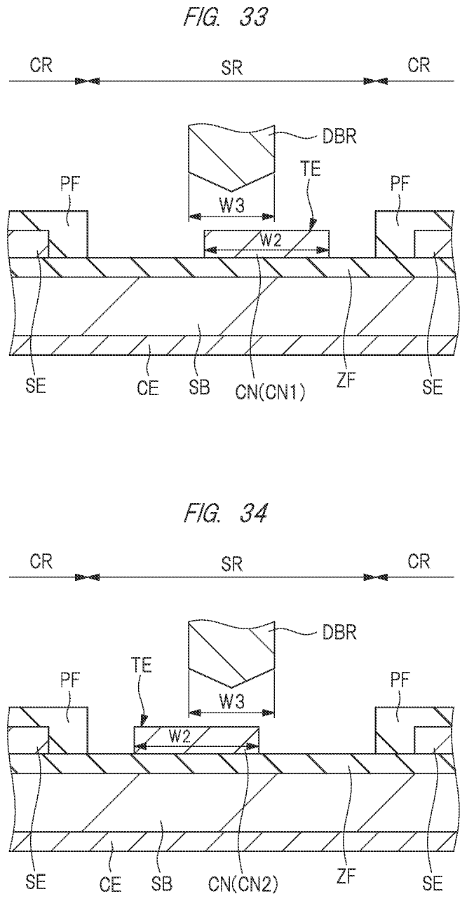

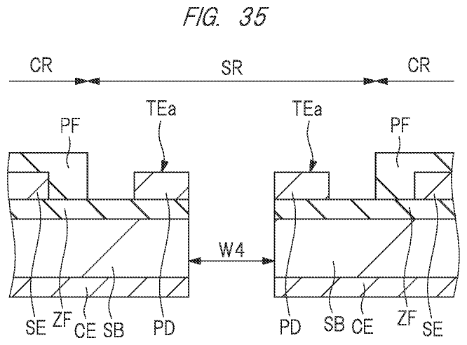

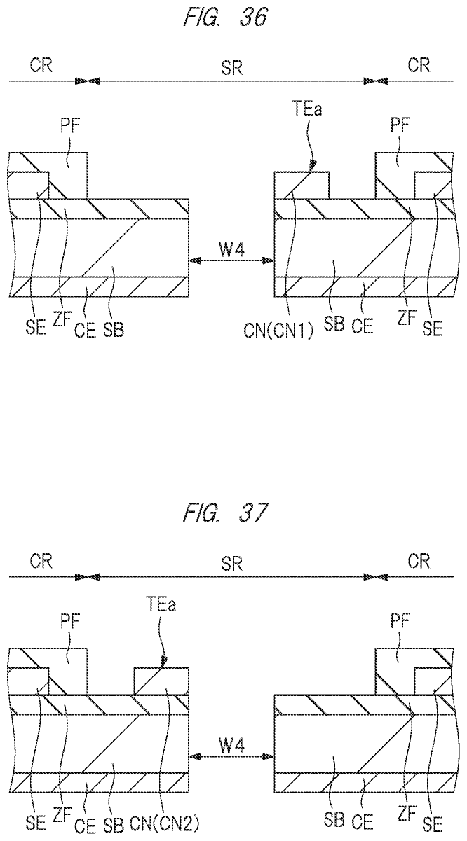

FIGS. 32 to 34 are cross-sectional views each illustrating a state of cutting of, by the dicing blade DBR, the scribe region SR of the semiconductor substrate SB in which the testing electrode TE of this embodiment is formed, and FIGS. 35 to 37 are cross-sectional views each illustrating a state of cutting (state after cutting), by the dicing blade DBR, the scribe region SR of the semiconductor substrate SB in which the testing electrode TE of this embodiment is formed. Each of FIGS. 32 and 35 corresponds to a cross section taken along line A1-A1 in FIGS. 17 and 18 (thus, the cross section corresponding to FIG. 19). Each of FIGS. 33 and 36 corresponds to a cross section taken along line A2-A2 in FIGS. 17 and 18 (thus, the cross section corresponding to FIG. 20). Each of FIGS. 34 and 37 corresponds to a cross section taken along line A3-A3 in FIGS. 17 and 18 (thus, the cross section corresponding to FIG. 21). FIG. 38 is a plan view illustrating a remaining cut-off piece of the testing electrode TE according to this embodiment after the dicing step.

In the dicing step, as illustrated in FIGS. 32 to 37, the scribe region SR of the semiconductor substrate SB in which the testing electrode TE of this embodiment is formed is cut by the dicing blade DBR. In this case, when the fact that the width W3 of the dicing blade DBR is smaller than the width W2 of the connection portion CN of the testing electrode TE (W2>W3) is reflected, the elongated metal pattern (metal piece) TEa formed by the remaining cut-off piece of the testing electrode TE remains as illustrated in FIG. 38. The metal pattern TEa illustrated in FIG. 38 corresponds to the remaining of the testing electrode TE illustrated in FIG. 17, from which a portion overlapping the cutting region RG1 cut by the dicing blade DBR is removed. The metal pattern TEa includes a metal pattern TEa (hereinafter, referred to as a metal pattern TEa1) including a remaining cut-off piece of the connection portion CN1 shifted toward the X1 direction and a metal pattern TEa (hereinafter, referred to as a metal pattern TEa2) including a remaining cut-off piece of the connection portion CN2 shifted toward the X2 direction, and the metal pattern TEa1 and the metal pattern TEa2 are separated from each other. The length (length in the Y direction) L2 of the elongated metal pattern TEa is shorter than the length (length in the Y direction) L1 of the testing electrode TE before the dicing step, and specifically, the length L2 is a total value of a value that is twice a length of the side SD3 of the pad portion PD and a length of the side SDI of the connection portion CN at the maximum (that is, L2=SD1+SD3×2).

This is because the metal pattern TEa1 including the remaining cut-off piece of the connection portion CN1 shifted toward the X1 direction and the metal pattern TEa2 including the remaining cut-off piece of the connection portion CN2 shifted toward the X2 direction are not unified with but separated from each other since the connection portion CN1 shifted toward the X1 direction and the connection portion CN2 shifted toward the X2 direction are alternately arranged to interpose the pad portion PD therebetween.

Specifically, when the connection portion CN1 and the connection portion CN2 satisfy the following conditions, the metal pattern TEa1 including the remaining cut-off piece of the connection portion CN1 and the metal pattern TEa2 including the remaining cut-off piece of the connection portion CN2 are separated from each other. That is, as seen from FIGS. 17 and 18, regarding the connection portion CN1, the side SD1 of the connection portion CN1 is not included in the cutting region RG1 cut by the dicing blade DRB in the dicing step, but the side SD2 of the connection portion CN1 is included in the cutting region RG1 cut by the dicing blade DRB in the dicing step. In addition, as seen from FIGS. 17 and 18, regarding the connection portion CN2, the side SD1 of the connection portion CN2 is included in the cutting region RG1 cut by the dicing blade DRB in the dicing step, but the side SD2 of the connection portion CN2 is not included in the cutting region RG1 cut by the dicing blade DRB in the dicing step. If the connection portion CN1 and the connection portion CN2 are arranged to satisfy this condition, the connection portion CN1 does not need to be divided into two by the dicing blade DRB, and the connection portion CN2 does not need to be divided into two by the dicing blade DRB, either, in the dicing step. Then, the metal pattern TEa1 including the remaining cut-off piece of the connection portion CN1 and the metal pattern TEa2 including the remaining cut-off piece of the connection portion CN2 are separated from each other.

The length (length in the Y direction) L2 of the metal pattern TEa1 including the remaining cut-off piece of the connection portion CN1 is shorter than the length (length in the Y direction) L1 of the testing electrode TE before the dicing step, and the length (length in the Y direction) L2 of the metal pattern TEa2 including the remaining cut-off piece of the connection portion CN2 is also shorter than the length (length in the Y direction) L1 of the testing electrode TE before the dicing step. The length L2 of each of the metal patterns TEa1 and TEa2 is at most a total value of a value that is twice the length of the side SD3 of the pad portion PD and the length of the side SD1 of the connection portion CN. This is because one side (side in the Y direction) of the metal pattern TEa1 is formed by the side SD1 of the connection portion CN1 and the sides SD3 of the two pad portions PD connected by the connection portion CN1. In addition, this is because one side (the side in the Y direction) of the metal pattern TEa2 is formed by the side SD2 of the connection portion CN2 and the sides SD4 of the two pad portions PD connected by the connection portion CN2 so that the length of the side SD1 and the length of the side SD2 are substantially the same while the length of the side SD3 and the length of the side SD4 are substantially the same.

In this embodiment, even when the length L1 of the testing electrode TE before the dicing step is long, the length L2 of the metal pattern TEa can be made shorter than the length L1 of the testing electrode TE before the dicing step (that is, L2<L1) even when the metal pattern TEa formed by the remaining cut-off piece of the testing electrode TE remains after the dicing step. Therefore, even when the metal pattern TEa scatters and is re-adhered onto the chip formation region CR (or the acquired semiconductor chip), the risk causing the defect can be reduced. This is because the longer the length L2 of the metal pattern Tea is, the higher the risk of the defect is, when the metal pattern TEa scatters and is re-adhered onto the chip formation region CR (or the acquired semiconductor chip).

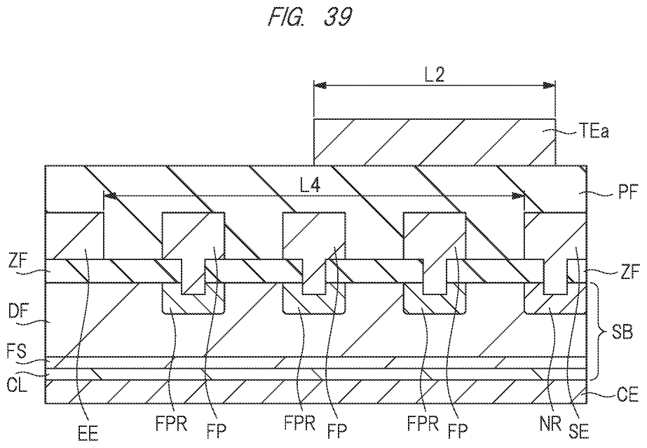

FIG. 39 is a cross-sectional view illustrating a state in which the scattered metal pattern TEa adheres onto the protective film PF and illustrates a cross section corresponding to FIG. 6. In this embodiment, even when the length L1 of the testing electrode TE before dicing is long, the length L2 of the metal pattern TEa remaining after the dicing step can be shortened, and thus the scattered metal pattern TEa can be suppressed or prevented from adhering onto the protective film PF to straddle the emitter electrode EE and the outer peripheral electrode SE. In addition, the scattered metal pattern TEa can be suppressed or prevented from adhering onto the protective film PF to straddle the gate electrode GE and the outer peripheral electrode SE.

That is, when the length L2 of the metal pattern TEa is long, there is the risk that the scattered metal pattern TEa adheres onto the protective film PF to straddle the emitter electrode EE and the outer peripheral electrode SE. However, when the length L2 of the metal pattern TEa is short, a possibility of adhering of the metal pattern TEa onto the protective film to straddle the emitter electrode EE and the outer peripheral electrode SE and a possibility of adhering of the metal pattern TEa onto the protective film to straddle the gate electrode GE and the outer peripheral electrode SE are reduced, even when the scattered metal pattern TEa adheres onto the protective film PF.

In addition, when the length L2 of the metal pattern TEa is smaller than a distance between the gate electrode GE and the outer peripheral electrode SE and smaller than a distance L4 between the emitter electrode EE and the outer peripheral electrode SE, the concern of adhering of the metal pattern TEa to straddle the emitter electrode EE and the outer peripheral electrode SE and the concern of adhering of the metal pattern TEa to straddle the gate electrode GE and the outer peripheral electrode SE are eliminated. As described above, the length L2 of the metal pattern TEa is at most the total value of the value that is twice the length of the side SD3 of the pad portion PD and the length of the side SD1 of the connection portion CN. Therefore, it is preferable that the total of the value that is twice the length of the side SD3 of the pad portion PD and the length of the side SD1 of the connection portion CN is smaller than the distance between the gate electrode GE and the outer peripheral electrode SE and smaller than the distance L4 between the emitter electrode EE and the outer peripheral electrode SE. Consequently, the concern of adhering of the metal pattern TEa to straddle the emitter electrode EE and the outer peripheral electrode SE and the concern of adhering of the metal pattern TEa to straddle the gate electrode GE and the outer peripheral electrode SE are eliminated. Further, the distance L4 between the emitter electrode E and the outer peripheral electrode SE is illustrated in FIGS. 31 and 39. In FIG. 39, when the emitter electrode EE is replaced with the gate electrode GE, the distance L4 illustrated in FIG. 39 indicates the distance between the gate electrode GE and the outer peripheral electrode SE. In addition, the distance L4 between the emitter electrode EE and the outer peripheral electrode SE corresponds to the nearest distance between the emitter electrode EE and the outer peripheral electrode SE, and the distance between the gate electrode GE and the outer peripheral electrode SE corresponds to the nearest distance between the gate electrode GE and the outer peripheral electrode SE.

In addition, the effect is significantly large when this embodiment is applied to a case where the length L1 of the testing electrode TE in the Y direction is larger than the distance between the gate electrode GE and the outer peripheral electrode SE or larger than the distance L4 between the emitter electrode EE and the outer peripheral electrode SE. The reason is as follows.

That is, it is assumed that the length L1 or L101 of the testing electrodes TE or TE101 before the dicing step is larger than the distance between the gate electrode GE and the outer peripheral electrode SE or larger than the distance L4 between the emitter electrode EE and the outer peripheral electrode SE. In this case, when not this embodiment but the above-described study example is applied, the length L102 of the metal pattern TE101a remaining after the dicing step is also larger than the distance between the gate electrode GE and the outer peripheral electrode SE or larger than the distance L4 between the emitter electrode EE and the outer peripheral electrode SE. In this case, there are the concern of adhering of the metal pattern TE101a to straddle the emitter electrode EE and the outer peripheral electrode SE and the concern of adhering of the metal pattern TE101a to straddle the gate electrode GE and the outer peripheral electrode SE. On the other hand, in this embodiment, even when the length L1 of the testing electrode TE is larger than the distance between the gate electrode GE and the outer peripheral electrode SE or larger than the distance L4 between the emitter electrode EE and the outer peripheral electrode SE, the length L2 of the metal pattern TEa remaining after the dicing step can be made shorter than the distance between the gate electrode GE and the outer peripheral electrode SE or the distance L4 between the emitter electrode EE and the outer peripheral electrode SE. Therefore, the concern of adhering of the metal pattern TEa to straddle the emitter electrode EE and the outer peripheral electrode SE and the concern of adhering of the metal pattern TEa to straddle the gate electrode GE and the outer peripheral electrode SE are eliminated.

In addition, in this embodiment, the testing electrode TE is configured to include the plurality of pad portions PD and the plurality of connection portions CN connecting the pad portions PD, and the plurality of connection portions CN is arranged in the staggered manner in the Y direction. Therefore, the testing electrode TE has three or more pad portions PD and two or more connection portions CN. In the testing electrode TE, each connection portion CN is a portion connecting two pad portions PD, and thus the number of connection portions CN included in the testing electrode TE is smaller by one than the number of pad portions PD included in the testing electrode TE.

When the number of pad portions PD included in the testing electrode TE is three, the pad portion PD, the connection portion CN1, the pad portion PD, the connection portion CN2, and the pad portion PD are arranged in this order in the Y direction, or the pad portion PD, the connection portion CN2, the pad portion PD, the connection portion CN1, and the pad portion PD are arranged in this order in the Y direction. When the number of pad portions PD included in the testing electrode TE is four, the pad portion PD, the connection portion CN1, the pad portion PD, the connection portion CN2, the pad portion PD, the connection portion CN1, and the pad portion PD are arranged in this order in the Y direction as illustrated in FIG. 18, or the pad portion PD, the connection portion CN2, the pad portion PD, the connection portion CN1, the pad portion PD, the connection portion CN2, and the pad portion PD are arranged in this order in the Y direction. When the number of pad portions PD included in the testing electrode TE is five, the pad portion PD, the connection portion CN1, the pad portion PD, the connection portion CN2, the pad portion PD, the connection portion CN1, the pad portion PD, the connection portion CN2, and the pad portion PD are arranged in this order in the Y direction, or the pad portion PD, the connection portion CN2, the pad portion PD, the connection portion CN1, the pad portion PD, the connection portion CN2, the pad portion PD, the connection portion CN1, and the pad portion PD are arranged in this order in the Y direction. The same applies when the number of pad portions PD included in the testing electrode TE is six or larger.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A method of manufacturing a semiconductor device comprising steps of:
(a) preparing a semiconductor substrate including a plurality of chip formation regions and a scribe region positioned between two chip formation regions of the plurality of chip formation regions, the two chip formation regions being adjacent to each other;
(b) after the step (a), forming a semiconductor element in each of the plurality of chip formation regions, and forming a dummy semiconductor element in the scribe region;
(c) after the step (b), inspecting the dummy semiconductor element by using a metal pattern which is provided in the scribe region and which is electrically connected to the dummy semiconductor element; and
(d) after the step (c), cutting the scribe region of the semiconductor substrate by using a dicing blade,
wherein the metal pattern includes:
a plurality of inspecting pad portions; and
a plurality of connection portions respectively provided between the plurality of inspecting pad portions, each of the plurality of connection portions connecting two inspecting pad portions of the plurality of inspecting pad portions to each other, the two inspecting pad portions being adjacent to each other,
wherein, in plan view, a width of each of the plurality of connection portions is larger than a width of the dicing blade, and smaller than a width of each of the plurality of inspecting pad portions, and
wherein, in plan view, the plurality of inspecting pad portions is arranged in a linear manner in a moving direction of the dicing blade, while the plurality of connection portions is arranged in a staggered manner in the moving direction of the dicing blade.

2. The method of manufacturing the semiconductor device according to claim 1,
wherein each of the plurality of connection portions has a first side and a second side which extend in the moving direction of the dicing blade and are positioned on opposite sides to each other in a first direction intersecting the moving direction of the dicing blade,
wherein the plurality of connection portions is formed of first connection portions and second connection portions which are alternately arranged with the respective inspecting pad portions interposed therebetween,
wherein the first side of the first connection portion is not included in a cutting region cut by the dicing blade in the step (d), but the second side of the first connection portion is included in the cutting region, and
wherein the first side of the second connection portion is included in the cutting region, but the second side of the second connection portion is not included in the cutting region.

3. The method of manufacturing the semiconductor device according to claim 2,
wherein each of the plurality of inspecting pad portions includes a third side and a fourth side which extend in the moving direction of the dicing blade and are positioned on opposite sides to each other in the first direction.

4. The method of manufacturing the semiconductor device according to claim 3,
wherein the first side of the first connection portion is aligned with the third side of the inspecting pad portion positioned adjacent to the first connection portion, and
wherein the second side of the second connection portion is aligned with the fourth side of the inspecting pad portion positioned adjacent to the first connection portion.

5. The method of manufacturing the semiconductor device according to claim 3,
wherein each of the semiconductor element and the dummy semiconductor element is an IGBT.

6. The method of manufacturing the semiconductor device according to claim 5,
wherein a gate electrode, an emitter electrode, and an outer peripheral collector electrode are formed on a front surface of the semiconductor chip acquired in the step (d), and a back surface collector electrode is formed on a back surface of the semiconductor chip opposite to the front surface, and
wherein, on the front surface of the semiconductor chip, the outer peripheral collector electrode is formed at an outer peripheral portion of the front surface of the semiconductor chip to surround the gate electrode and the emitter electrode.

7. The method of manufacturing the semiconductor device according to claim 6,
wherein a total of a value which is twice a length of the first side and a length of the third side is smaller than a distance between the gate electrode and the outer peripheral collector electrode, and is smaller than a distance between the emitter electrode and the outer peripheral collector electrode.

8. The method of manufacturing the semiconductor device according to claim 7,
wherein a length of the metal pattern in the moving direction of the dicing blade is larger than the distance between the gate electrode and the outer peripheral collector electrode, or is larger than the distance between the emitter electrode and the outer peripheral collector electrode.

9. The method of manufacturing the semiconductor device according to claim 7,
wherein a field plate electrode is formed between the outer peripheral collector electrode and the gate electrode/emitter electrode on the front surface of the semiconductor chip.

10. The method of manufacturing a semiconductor device according to claim 5,
wherein the metal pattern is an emitter electrode for the IGBT, the emitter electrode configuring the dummy semiconductor element.

11. A method of manufacturing a semiconductor device comprising steps of:
(a) preparing a semiconductor substrate including a plurality of chip formation regions and a scribe region positioned between two chip formation regions of the plurality of chip formation regions, the two chip formation regions being adjacent to each other;
(b) after the step (a), forming a semiconductor element in each of the plurality of chip formation regions and forming a dummy semiconductor element in the scribe region;
(c) after the step (b), inspecting the dummy semiconductor element by using a metal pattern which is provided in the scribe region and is electrically connected to the dummy semiconductor element; and
(d) after the step (c), cutting the scribe region of the semiconductor substrate by using a dicing blade;
wherein the metal pattern includes:
a plurality of inspecting pad portions; and
a plurality of connection portions respectively provided between the plurality of inspecting pad portions, each of the plurality of connection portions connecting two inspecting pad portions of the plurality of inspecting pad portions, the two inspecting pad portions being adjacent to each other,
wherein, in plan view, a width of each of the plurality of connection portions is larger than a width of the dicing blade, and is smaller than a width of each of the plurality of inspecting pad portions,
wherein each of the plurality of connection portions includes
a first side extending in a moving direction of the dicing blade, and
a second side extending in the moving direction of the dicing blade and positioned on an opposite side to the first side in a first direction intersecting the moving direction,
wherein the plurality of connection portions is formed of a first connection portion and a second connection portion which are alternately arranged via each of the inspecting pad portions,
wherein, in plan view, the plurality of inspecting pad portions is arranged in a linear manner in the moving direction of the dicing blade, and
wherein, in the step (d), each of the second side of the first connection portion and the first side of the second connection portion is included in a cutting region cut by the dicing blade, but each of the first side of the first connection portion and the second side of the second connection portion is not included in the cutting region.
